(19) United States
(12) Patent Application Publication
(10) Pub. No.: US 2025/0248040 A1
(43) Pub. Date: Jul. 31, 2025

(54) THREE-DIMENSIONAL MEMORY DEVICE HAVING A COMPACT WORD LINE DRIVER TRANSISTOR LAYOUT

(71) Applicant: SANDISK TECHNOLOGIES LLC, ADDISON, TX (US)

(72) Inventors: Qinghua ZHAO, San Jose, CA (US); Sudarshan NARAYANAN, San Jose, CA (US); Mohan DUNGA, Santa Clara, CA (US); Hiroki YABE, Yokkaichi (JP); Masahito TAKEHARA, Yokkaichi (JP)

(21) Appl. No.: 18/423,770

(22) Filed: Jan. 26, 2024

(51) Int. Cl. H10B 43/35; H01L 27/06; H01L 27/088; H10B 43/27; H10B 51/20; H10B 63/10

(52) U.S. Cl. CPC H10B 43/35; H10B 43/27; H10B 51/20; H10B 63/10; H10D 84/83; H10D 88/00

(57) ABSTRACT

A memory device includes a plurality of memory blocks including respective word lines; and a word line driver circuit including word line driver transistors. In one embodiment, the word line driver transistors are located in laterally offset rows. In another embodiment, at least one of a spacing between laterally adjacent word line driver transistors or a length of their source or drain region differs dependent on whether the transistors are connected to words lines in the same memory block or in different memory blocks.

### FIELD

The present disclosure relates generally to the field of semiconductor devices, and particularly to a three-dimensional memory device having a compact word line driver transistor layout.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device comprises: a plurality of memory blocks comprising respective word lines; and a word line driver circuit comprising rows of first word line driver transistors having a source-drain direction and additional rows of second word line driver transistors having the same source-drain direction as the first word line driver transistors. The first word line driver transistors comprise first output nodes electrically connected to word lines in a first memory block of the plurality of memory blocks; the second word line driver transistors comprise second output nodes electrically connected to word lines in the first memory block of the plurality of memory blocks; and the rows of the first word line driver transistors are laterally offset from the additional rows of the second word line driver transistors along the source-drain direction.

According to another aspect of the present disclosure, a memory device comprises a plurality of memory blocks comprising respective word lines; and a word line driver circuit comprising a first word line driver transistor having a source-drain direction, and second, third and fourth word line driver transistors having the same source-drain direction as the first word line driver transistors. The first word line driver transistor comprises a first output node having a first length electrically connected to a word line in a first memory block of the plurality of memory blocks. The second word line driver transistor comprises a second output node having the first length electrically connected to another word line in the first memory block. The third word line driver transistor comprises a first output node having a second length electrically connected to yet another word line in the first memory block. The fourth word line driver transistor comprises a second output node having the second length electrically connected to a word line in a second memory block of the plurality of memory blocks. The first word line driver transistor and the second word line driver transistor are laterally spaced apart along the source-drain direction apart by a first lateral spacing. The third word line driver transistor and the fourth word line driver transistor are laterally spaced apart along the source-drain direction apart by a second lateral spacing. The second lateral spacing is larger than the first lateral spacing and/or the second length is longer than the first length.

According to another aspect of the present disclosure, a semiconductor structure comprises a bonded assembly of a memory die and a logic die. The memory die comprises a plurality of memory blocks including a respective alternating stack of insulating layers and word lines and including a respective set of rows of memory opening fill structures vertically extending through the respective alternating stack and arranged along a first horizontal direction, wherein the memory blocks are laterally spaced apart among one another along a second horizontal direction that is perpendicular to the first horizontal direction with a uniform block-to-block pitch. The logic die comprises a first two-dimensional array of first word line driver transistors including multiple rows of first word line driver transistors and a second two-dimensional array of second word line driver transistors including multiple rows of second word line driver transistors, wherein each row of first word line driver transistors is arranged along the first horizontal direction and each row of second word line driver transistors is arranged along the first horizontal direction, wherein each of the first word line driver transistors and the second word line driver transistor comprises a first output node that is electrically connected to a respective first word line among the word lines of the memory blocks and laterally spaced from a common input node by a respective first control gate electrode along the second horizontal direction, and further comprises a second output node that is electrically connected to a respective second word line among the word lines of the memory blocks and laterally spaced from the common input node by a respective second control gate electrode along a direction that is an opposite direction of the second horizontal direction. The multiple rows of first word line driver transistors have a periodic modulation in a first row-to-row spacing along the second horizontal direction, the first row-to-row spacing being measured by a lateral spacing between a neighboring pair of first word line driver transistors that are laterally spaced along the second horizontal direction.

### BRIEF DESCRIPTION OF THE DRAWINGS

FIG. 1A is a schematic vertical cross-sectional view of an exemplary structure after formation of memory opening fill structures and support pillar structures according to an embodiment of the present disclosure.

FIG. 1B is a top-down view of the exemplary structure of FIG. 1A. The vertical plane A-A is the cut plane of the vertical cross-sectional view of FIG. 1A.

FIG. 1C is a vertical cross-sectional view of a region of the exemplary structure around a memory opening fill structure.

FIG. 2A is a vertical cross-sectional view of the exemplary structure after formation of lateral isolation trenches according to an embodiment of the present disclosure.

FIG. 2B is a top-down view of the exemplary structure of FIG. 2A. The vertical plane A-A is the cut plane of the vertical cross-sectional view of FIG. 2A.

FIG. 3 is a schematic vertical cross-sectional view of the exemplary structure after formation of electrically conductive layers according to an embodiment of the present disclosure.

FIG. 4A is a vertical cross-sectional view of the exemplary structure after formation of lateral isolation trench fill structures, layer contact via structures, and drain contact via structures according to an embodiment of the present disclosure.

FIG. 4B is a top-down view of the exemplary structure of FIG. 4A. The vertical plane A-A is the cut plane of the vertical cross-sectional view of FIG. 4A.

FIG. 5A is a vertical cross-sectional view of the exemplary structure after formation of bit-line-level metal interconnect structures according to an embodiment of the present disclosure.

FIG. 5B is a top-down view of the exemplary structure of FIG. 5A. The vertical plane A-A is the cut plane of the vertical cross-sectional view of FIG. 5A.

FIG. 6 is a vertical cross-sectional view of the exemplary structure after formation of a memory die according to an embodiment of the present disclosure.

FIG. 7 is a vertical cross-sectional view of a logic die according to an embodiment of the present disclosure.

FIG. 8 is a vertical cross-sectional view of the exemplary structure after attaching the logic die to the memory die according to an embodiment of the present disclosure.

FIG. 9 is a vertical cross-sectional view of the exemplary structure after removal of the substrate according to an embodiment of the present disclosure.

FIG. 10A is a vertical cross-sectional view of the exemplary structure after formation of source structures according to an embodiment of the present disclosure.

FIG. 10B is a magnified view of a region of the exemplary structure of FIG. 10A.

FIG. 11 is a vertical cross-sectional view of the exemplary structure after formation of a backside dielectric layer and source contact structures according to an embodiment of the present disclosure.

FIG. 12 is a plan view of a first configuration of the exemplary structure in which word line driver transistors in the logic die are juxtaposed over blocks in the memory die.

FIGS. 13A-13D are plan views of second configurations of the exemplary structure in which word line driver transistors in the logic die are shown according to an embodiment of the present disclosure.

FIGS. 14A and 14B are plan views of third configurations of the exemplary structure in which word line driver transistors in the logic die are juxtaposed over blocks in the memory die according to an embodiment of the present disclosure.

FIGS. 15A and 15B are plan views of fourth configurations of the exemplary structure in which word line driver transistors in the logic die are shown according to an embodiment of the present disclosure.

FIG. 16 is a plan view of a fifth configuration of the exemplary structure in which word line driver transistors in the logic die are shown according to an embodiment of the present disclosure.

FIG. 17 is a plan view of a sixth configuration of the exemplary structure in which word line driver transistors in the logic die are shown according to an embodiment of the present disclosure.

FIG. 18 is a plan view of a seventh configuration of the exemplary structure in which word line driver transistors in the logic die are shown according to an embodiment of the present disclosure.

FIGS. 19A and 19B are first schematic diagrams illustrating the spatial overlap between transistor groups in the logic die and memory blocks in the memory die according to an embodiment of the present disclosure.

FIGS. 19C and 19D are plan views of two types of transistors in the same transistor group shown in FIG. 19A or FIG. 19B.

FIG. 20 is a second schematic diagram illustrating the spatial overlap between transistor groups in the logic die and memory blocks in the memory die according to an embodiment of the present disclosure.

### DETAILED DESCRIPTION

As discussed above, the embodiments of the present disclosure are directed to a three-dimensional memory device having a compact word line driver transistor layout the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

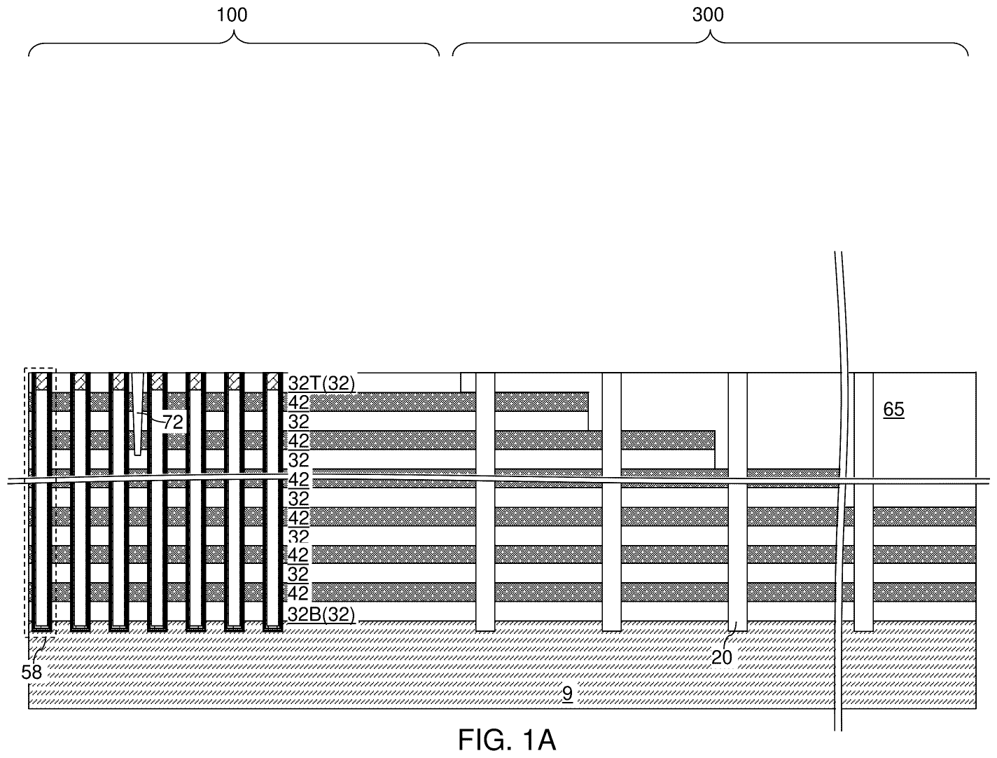

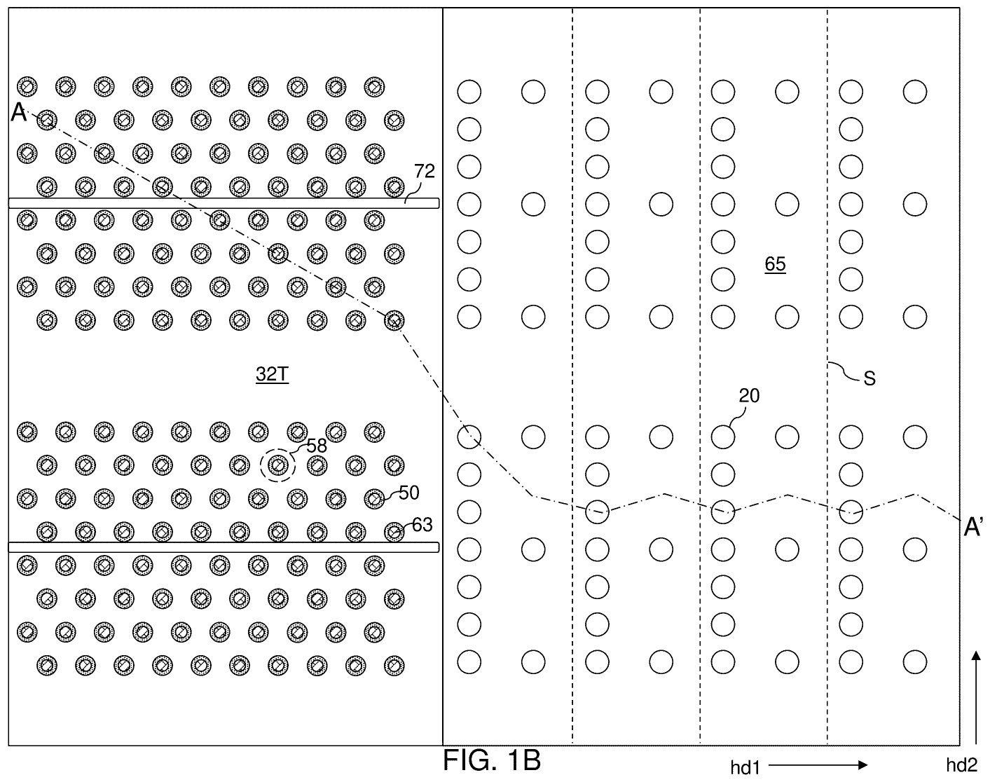

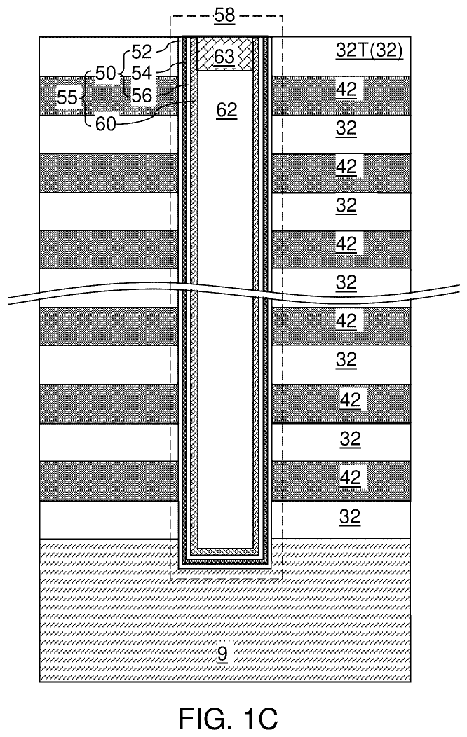

Referring to FIGS. 1A-1C, an exemplary structure according to an embodiment of the present disclosure is illustrated. The exemplary structure comprises a substrate 9, which may be a semiconductor substrate or a conductive substrate. For example, the substrate 9 may comprise a commercially available silicon wafer. Alternatively, the substrate 9 may comprise any material that may be removed selective the materials of insulating layers 32 and dielectric material portions to be subsequently formed.

An alternating stack of first material layers and second material layers can be formed over the substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 can be formed through a subset of the material layers in the alternating stack (32, 42) that is located in the top portion of the alternating stack (32, 42). The drain-select-level isolation structures 72 may laterally extend along the first horizontal direction hd1.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

Stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

A first etch mask layer (not shown) can be formed over the alternating stack (32, 42), and can be lithographically patterned to form openings in the contact region 300. An anisotropic etch process can be performed to transfer the pattern of the openings in the first etch mask layer through the stepped dielectric material portion 65 and the alternating stack (32, 42). Support openings can optionally be formed through the stepped dielectric material portion 65 and the alternating stack (32, 42) in the contact region 300. Each of the support openings can vertically extend into the substrate 9. In one embodiment, bottom surfaces of the support openings may be formed at or below the top surface of the substrate 9. The support openings may have a diameter in a range from 60 nm to 400 nm, such as from 120 nm to 300 nm, although lesser and greater thicknesses may be employed.

A dielectric fill material, such as silicon oxide, can be deposited in the support openings by a conformal deposition process. Excess portions of the dielectric fill material can be removed from above the top surface of the topmost insulating layer 32T, for example, by a recess etch process. Each portion of the dielectric fill material that fills a respective support opening constitutes a support pillar structure 20, which can be employed to provide structural support to the insulating layers 32 and the stepped dielectric material portion 65 during replacement of the sacrificial material layers 42 with electrically conductive layers. Alternatively, the support openings can be formed at a later step at the same time as the memory openings, and the support pillar structures 20 can be formed in the support openings at the same time as the memory opening fill structures are formed in the memory openings, as will be described below.

A second etch mask layer can be formed over the alternating stack (32, 42), and can be lithographically patterned to form openings in the memory array region 100. An anisotropic etch process can be performed to transfer the pattern of the openings in the second etch mask layer through the alternating stack (32, 42). Memory openings can be formed through the alternating stack (32, 42) in the memory array region 100.

Each cluster of memory openings may comprise a plurality of rows of memory openings. Each row of memory openings may comprise a plurality of memory openings that are arranged along the first horizontal direction hd1 with a uniform pitch. The rows of memory openings may be laterally spaced among one another along the second horizontal direction hd2, which may be perpendicular to the first horizontal direction hd2. In one embodiment, each cluster of memory openings may be formed as a two-dimensional periodic array of memory openings. The memory openings may have a diameter in a range from 60 nm to 400 nm, such as from 120 nm to 300 nm, although lesser and greater thicknesses may be employed. In the alternative embodiment, the support openings are formed at the same time as the memory openings using the same patterned photoresist layer.

A memory opening fill structure 58 can be formed in each memory opening. For example, a layer stack including a memory material layer 54 can be conformally deposited in each memory opening. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

A semiconductor channel material layer can be deposited over each memory film 50 by performing a conformal deposition process. If the semiconductor channel material layer is doped, the semiconductor channel material layer may have a doping of a first conductivity type, which may be p-type or n-type. The thickness of the semiconductor channel material layer may be in a range from 5 nm to 50 nm, such as from 10 nm to 30 nm, although lesser and greater thicknesses may also be employed.

A dielectric core layer comprising a dielectric fill material, such as silicon oxide, can be deposited in remaining volumes of the memory openings. While the dielectric core layer can be deposited employing a conformal deposition process, such as a chemical vapor deposition process, the conformity of the conformal deposition process may not be perfect. Thus, the thickness of a bottom portion of the dielectric core layer at the bottom of each memory opening may be less than the thickness of an upper portion of the dielectric core layer at the top of each memory opening. The dielectric core layer can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer (which has a doping of the first conductivity type) constitutes a vertical semiconductor channel 60.

Each portion of the layer stack including the memory material layer 54 that remains in a respective memory opening constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers. In the alternative embodiment, the support pillar structures 20 may be formed in the support openings at the same time as the memory opening fill structures 58 are formed in the memory openings. In this case, the support pillar structures 20 comprise the same materials as the memory opening fill structures 58.

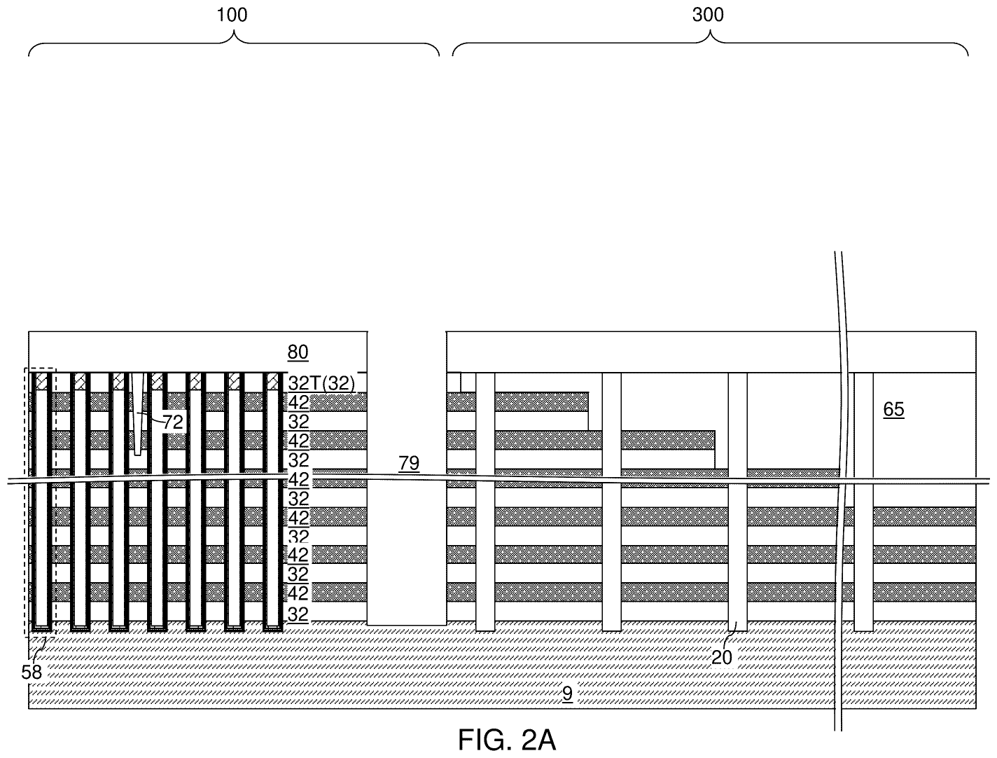

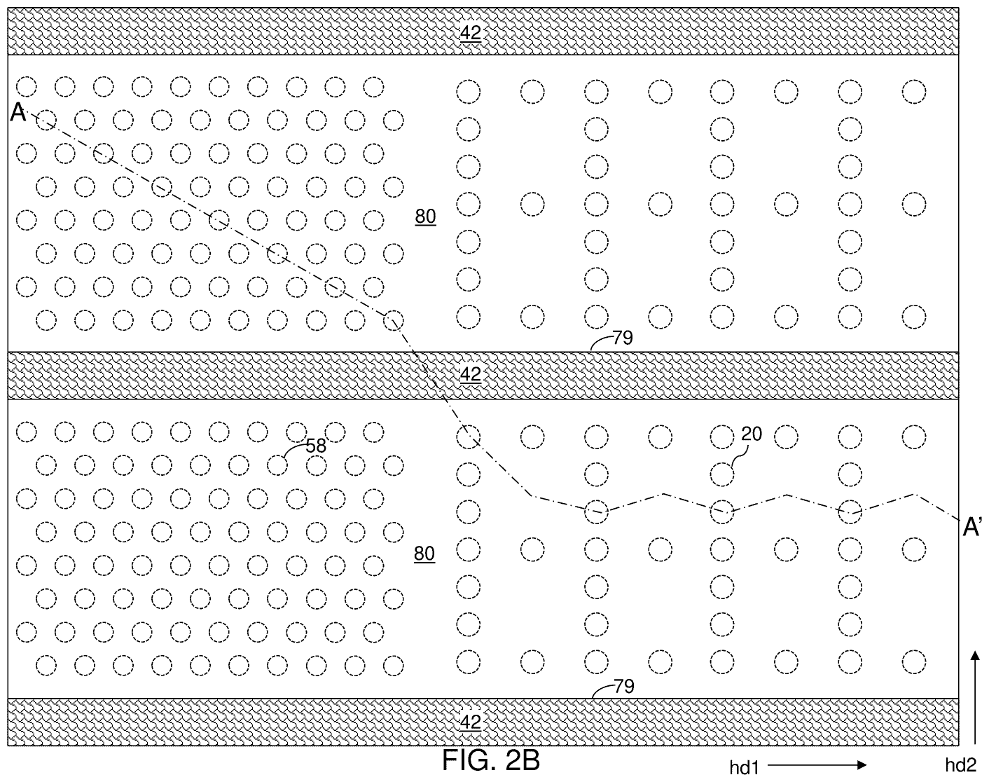

Referring to FIGS. 2A and 2B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the substrate 9. The photoresist layer can be subsequently removed, for example, by ashing.

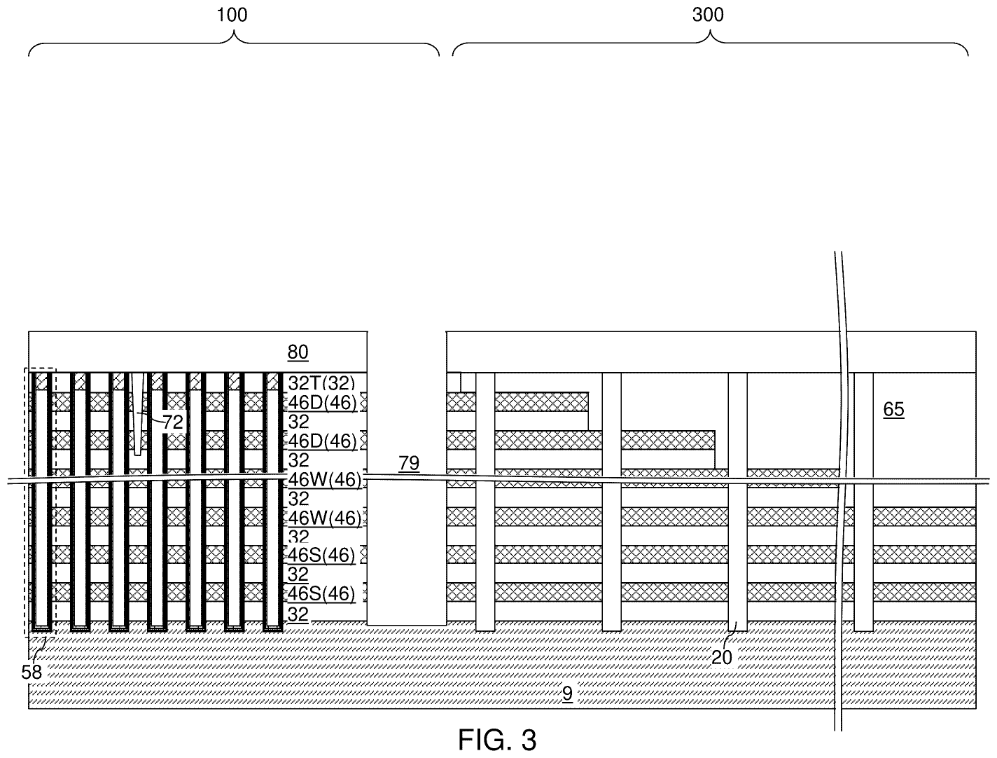

Referring to FIG. 3, an etchant that selectively etches the material of the sacrificial material layers 42 with respect to the material of the insulating layers 32 can be introduced into the access trenches 79, for example, employing an isotropic etch process. Lateral recesses are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the access trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses are present within volumes previously occupied by the sacrificial material layers 42.

Each lateral recess can be a laterally extending cavity having a lateral dimension that is greater than the vertical extent of the cavity. In other words, the lateral dimension of each lateral recess can be greater than the height of the lateral recess. A plurality of lateral recesses can be formed in the volumes from which the second material of the sacrificial material layers 42 is removed. The memory openings in which the memory stack structures 55 are formed are herein referred to as front side openings or front side cavities in contrast with the lateral recesses.

Each of the plurality of lateral recesses can extend substantially parallel to the top surface of the substrate 9. A lateral recess can be vertically bounded by a top surface of an underlying insulating layer 32 and a bottom surface of an overlying insulating layer 32. In one embodiment, each lateral recess can have a uniform height throughout.

An outer blocking dielectric layer can be optionally formed. The outer blocking dielectric layer, if present, comprises a dielectric material that functions as a control gate dielectric for the control gates to be subsequently formed in the lateral recesses. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses by providing at least one reactant gas into the lateral recesses through the access trenches 79. A metallic barrier layer can be deposited in the lateral recesses. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses, on the sidewalls of the at least one the access trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses, and a continuous metallic material layer can be formed on the sidewalls of each access trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the access trenches 79 or above the contact-level dielectric layer 80.

The deposited metallic material of the continuous electrically conductive material layer is etched back from the sidewalls of each access trench 79 and from above the contact-level dielectric layer 80 by performing an isotropic etch process that etches the at least one conductive material of the continuous electrically conductive material layer. Each remaining portion of the deposited metallic material in the lateral recesses constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses.

At least one uppermost electrically conductive layer 46 may comprise at least one drain side select gate electrode 46D. At least one bottommost electrically conductive layer 46 may comprise at least one source side select gate electrode 46S. The remaining electrically conductive layers 46 may comprise word lines 46W. Each word line functions as a common control gate electrode for the plurality of vertical NAND strings (e.g., memory opening fill structures 58).

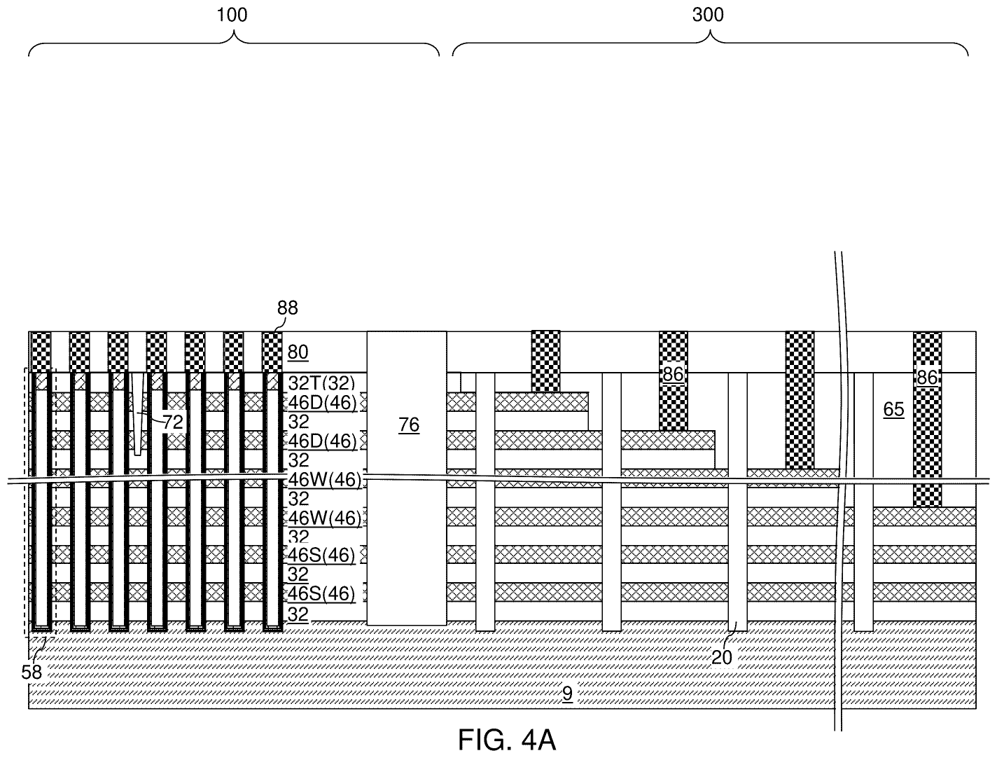

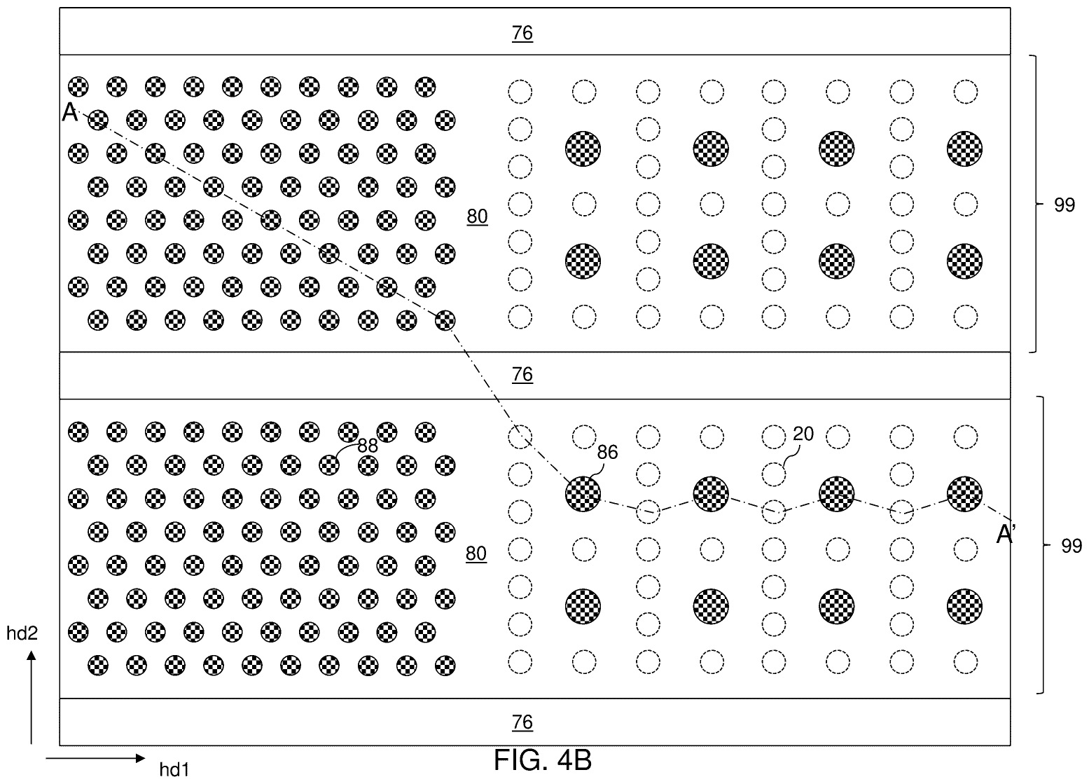

Referring to FIGS. 4A and 4B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure. The areas between adjacent lateral isolation trench fill structures 76 correspond to respective memory blocks (99A, 99B), as shown in FIG. 4B.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

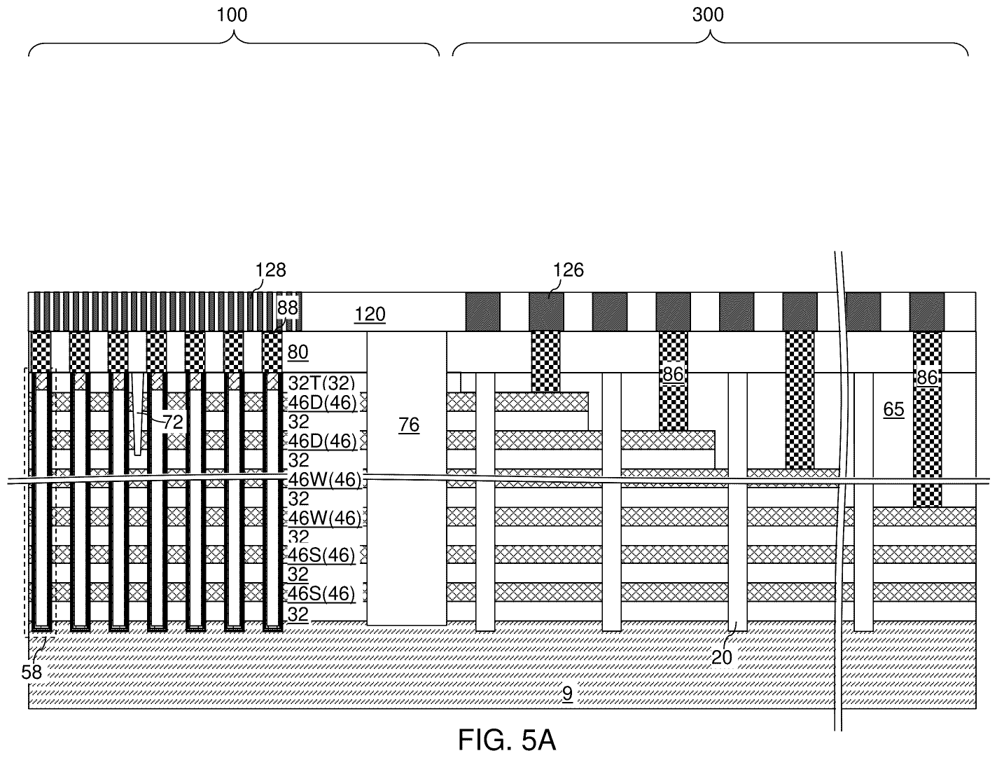

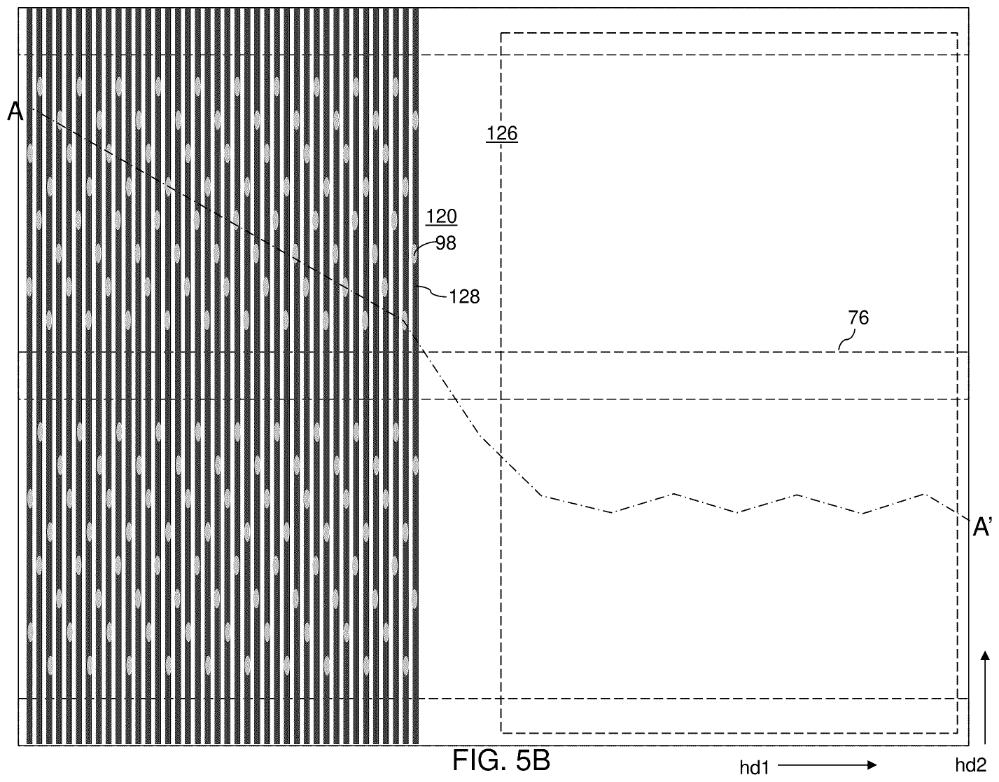

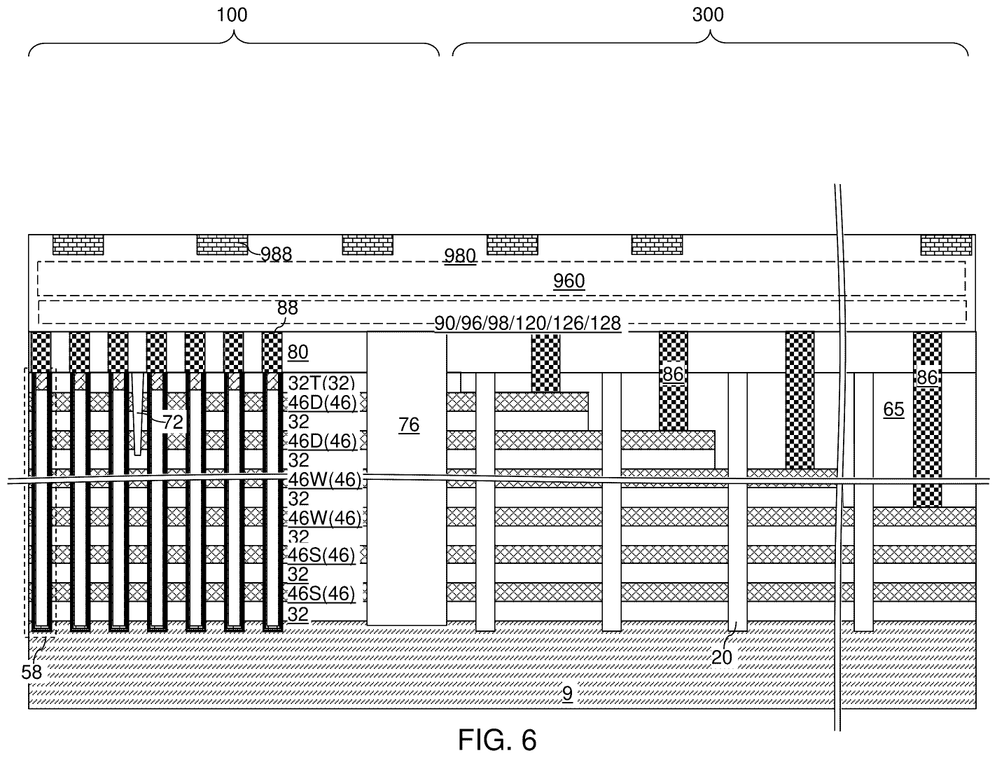

Referring to FIGS. 5A and 5B, a bit-line-level dielectric layer 120 can be formed above the contact-level dielectric layer 80. Bit-line-level line cavities can be formed through the bit-line-level dielectric layer 120, and can be filled with at least one conductive material (which may comprise at least one metallic material) to form bit-line-level metal lines (128, 126). The bit-line-level metal lines 128 may comprise bit lines 128 that laterally extend along the second horizontal direction hd2, and bit-line-level interconnect metal lines 126 (not individually shown) that can be employed to provide electrical connection to the layer contact via structures 86.

Referring to FIG. 60, additional dielectric material layers and additional metal interconnect structures can be formed over the bit-line-level dielectric layer 120. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

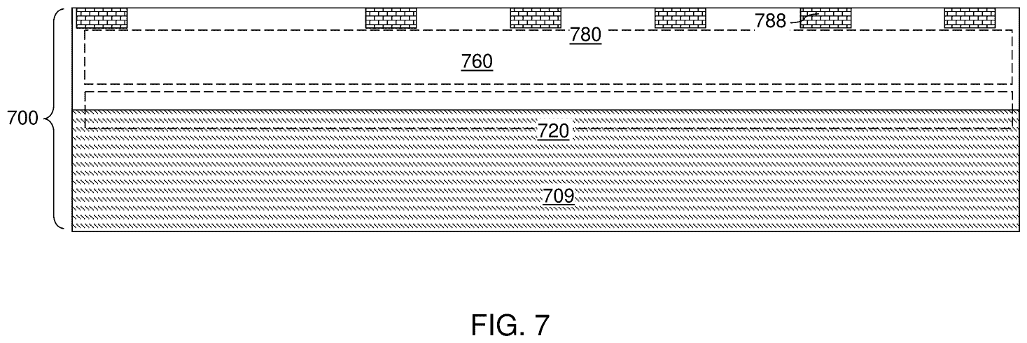

Referring to FIG. 7, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines 46W in the memory die 900.

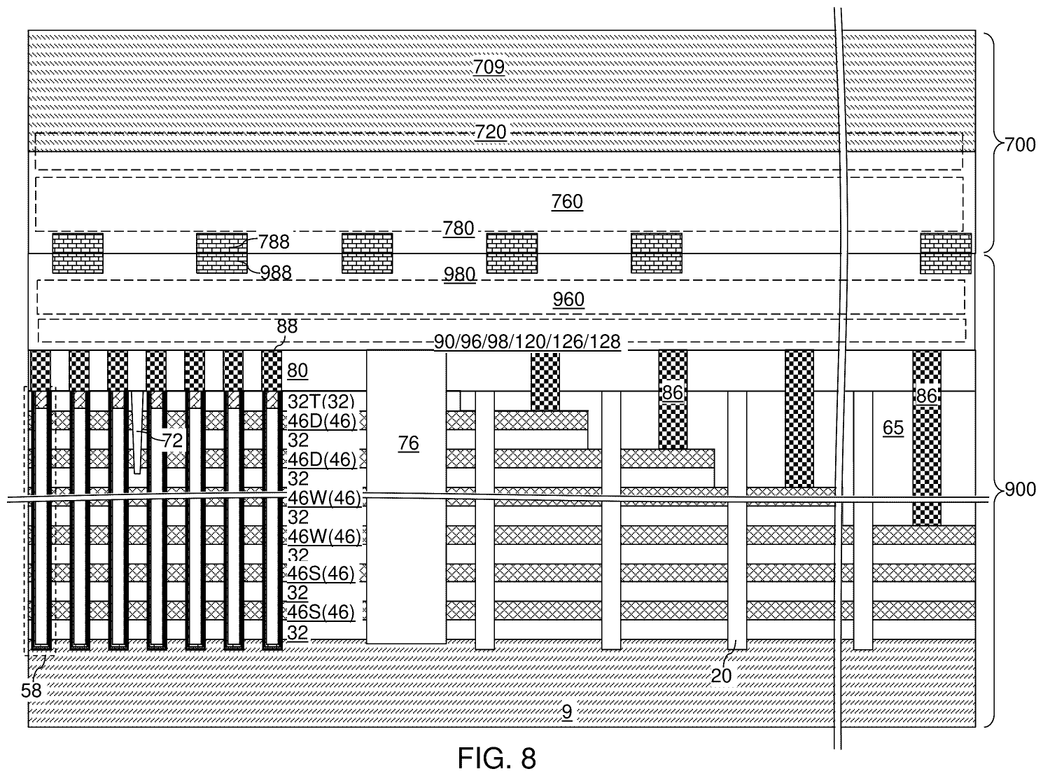

Referring to FIG. 8, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

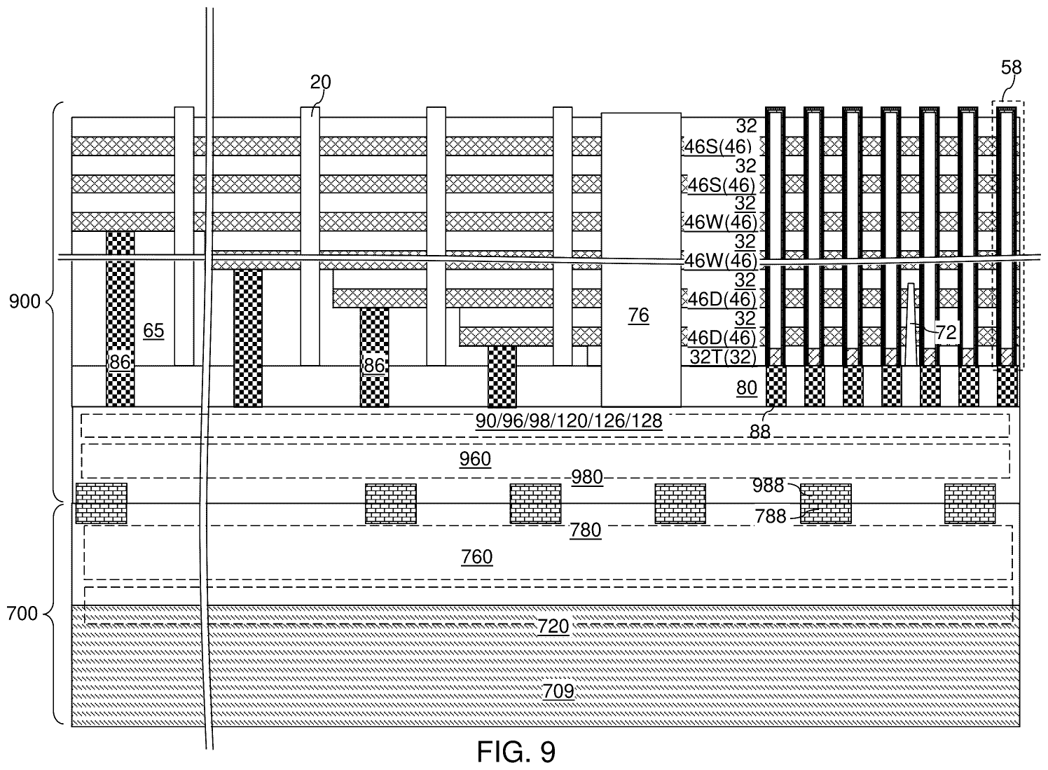

Referring to FIG. 9, the substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selective to dielectric materials of the memory films 50. In an illustrative example, if the substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

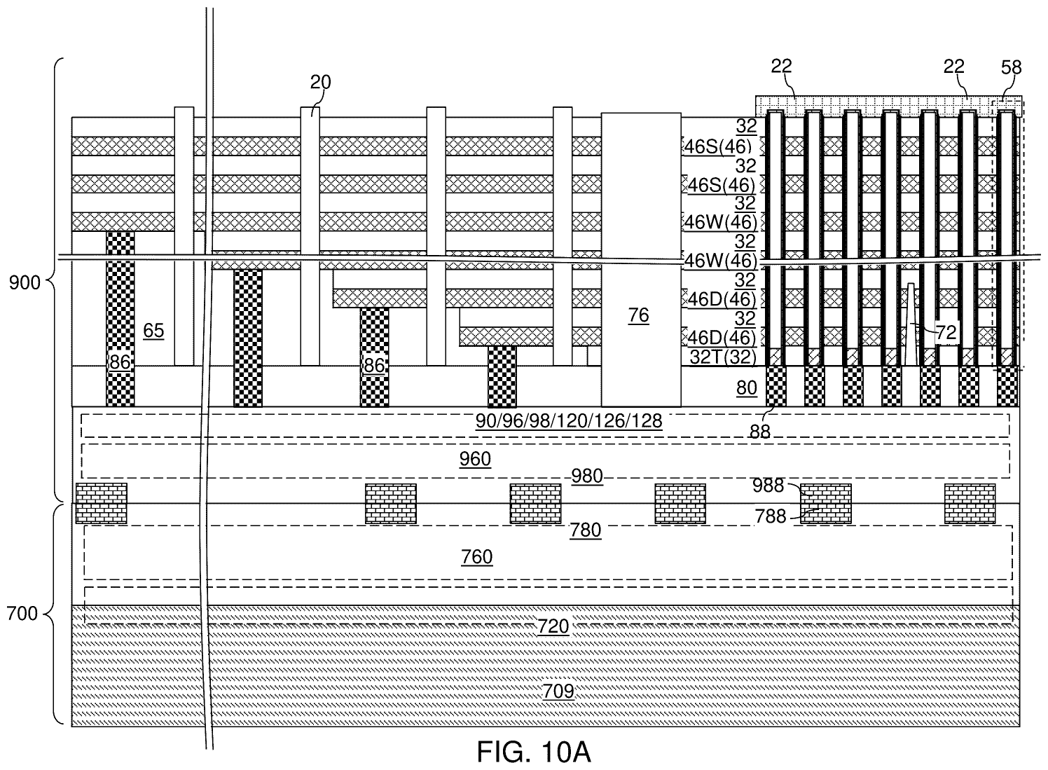

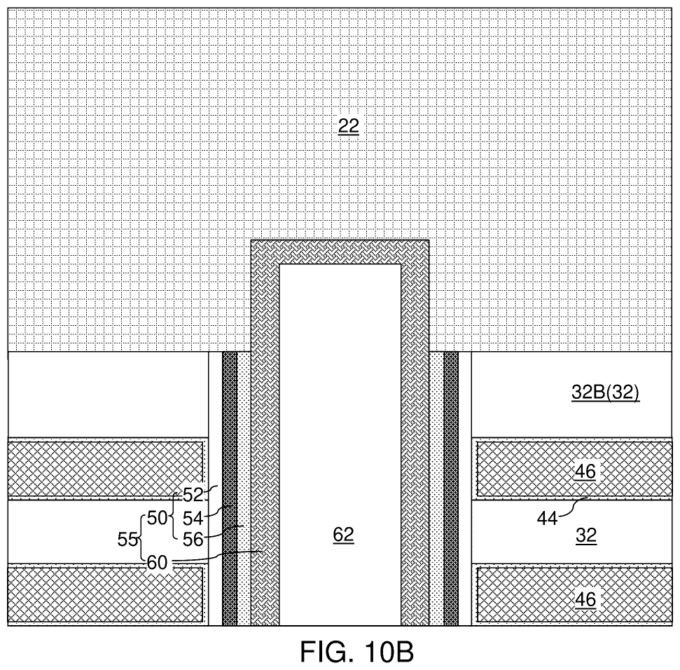

Referring to FIGS. 10A and 10B, an end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

One or more source structures (e.g., one or more source lines) 22 can be formed in contact vertical semiconductor channels 60. The source structure 22 may comprise a heavily doped semiconductor material and/or a metallic material (e.g., a metal and/or an electrically conductive metal nitride or silicide). Optional outer blocking dielectric layers 44 are illustrated in FIG. 10B, each of which embeds a respective electrically conductive layer 46. Alternatively, the optional outer blocking dielectric layers 44 may be omitted.

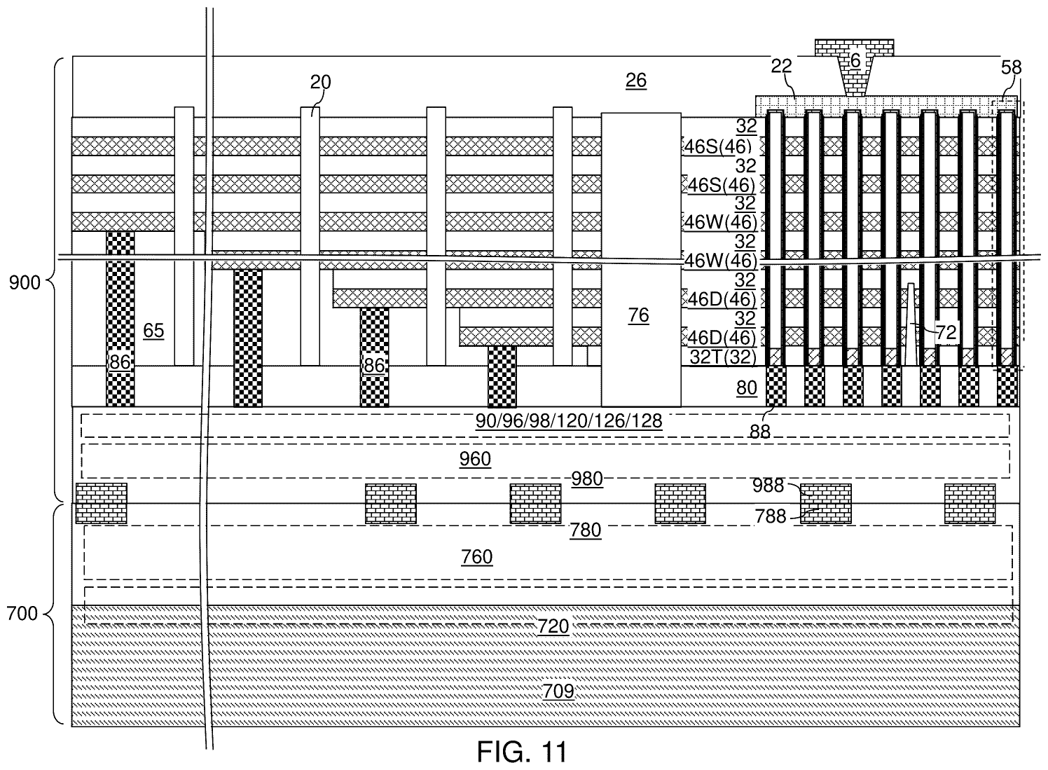

Referring to FIG. 11, a backside dielectric layer 26 and source contact structures 6 can be subsequently formed in contact with the one or more source structures 22.

While a bonded assembly of a memory die 900 and the logic die 700 are described above, in an alternative embodiment, the peripheral circuit 720 and the memory array (32, 46, 58) may be located in the same die. In this alternative embodiment, the peripheral circuit 720 may be formed over the substrate 9 and the memory array (32, 46, 58) is then formed over the peripheral circuit 720.

FIG. 12 is a plan view of a first configuration of the exemplary structure in which word line driver transistors 722 in the logic die 700 are juxtaposed over memory blocks in the memory die 900. In the illustrated example, the area of a first memory block 99A is represented by “BLOCK A,” and the area of a second memory block 99B is represented by “BLOCK B.” Generally, the memory die 900 comprises a plurality of memory blocks (99A, 99B) including a respective alternating stack of insulating layers 32 and word lines 46W and including a respective set of rows of memory opening fill structures 58 vertically extending through the respective alternating stack and arranged along a first horizontal direction hd1. The memory blocks (99A, 99B) are laterally spaced apart from each other along a second horizontal direction hd2 that is perpendicular to the first horizontal direction hd1 with a uniform block-to-block pitch p_bb. The first horizontal direction hd1 can be the word line 46W direction, and the second horizontal direction hd2 can be the bit line 128 direction. In one embodiment described above with respect to FIG. 4B, adjacent memory blocks (99A, 99B) may be spaced apart from each other along the second horizontal direction hd2 by the respective lateral isolation trench fill structure 76. Thus, each area of the memory die 900 between two adjacent lateral isolation trench fill structures 76 may comprise a respective memory block (99A, 99B).

The peripheral circuit 720 in the logic die 700 comprises multiple groups of word line driver transistors 722. For example, a first group of word line driver transistors 722 labeled as “Transistor group A” and a second group of word line driver transistors 722 labeled as “Transistor group B” may be arranged in the logic die 700 along the first horizontal direction hd1, which is the word line direction in the three-dimensional memory array in the memory die 900. The first group of word line driver transistors 722 includes first word line driver transistors 722A, and the second group of word line driver transistors 722 includes second word line driver transistors 722B.

In one embodiment, the logic die 700 comprises first word line driver transistors 722A (such as the first group of word line driver transistors 722 in Transistor group A) and second word line driver transistors 722B (such as the second group of word line driver transistors 722 in Transistor group B). Each of the first word line driver transistors 722A and the second word line driver transistor 722B comprises a first output node (i.e., a bias voltage-out node 1) that is electrically connected to a respective first word line 46W and laterally spaced from a common input node (i.e., a bias voltage-in node 3) by a respective first control gate electrode 11 along the second horizontal direction hd2, and further comprises a second output node (i.e., a bias voltage-out node 2) that is electrically connected to a respective second word line 46W and laterally spaced from the common input node (i.e., the bias voltage-in node 3) by a respective second control gate electrode 12 along a direction that is an opposite direction of the second horizontal direction hd2. In one embodiment, within each first word line driver transistor 722A and within each second word line driver transistor 722A, the first output node, the second output node, and the common input node comprise a respective first source/drain region, a respective second source/drain region, and a respective third source/drain region that are portion of a respective active semiconductor region 4 that is laterally surrounded by a dielectric isolation structure (such as a shallow isolation trench structure). The active region 4 includes the source/drain regions (1, 2, 3) and a semiconductor channel region between the source/drain regions. The bias voltage-out nodes 1 and 2 may comprise transistor 722 drain regions and the bias voltage-in node 3 may comprise transistor source region, or vice-versa.

In one embodiment, the first word line driver transistors 722A are arranged in rows that extend along the first horizontal direction hd1 and spaced apart from each other along the second horizontal direction hd2. In one embodiment, the second word line driver transistors 722B are arranged in additional rows that extend along the first horizontal direction hd1 and spaced apart from each other along the second horizontal direction hd2. In one embodiment, the rows of the first word line driver transistors 722A and the additional rows of the second word line driver transistors 722B are offset along the second horizontal direction hd2 by a lateral offset distance, such as a uniform first lateral offset distance LOD1.

In one embodiment, each source/drain region of the first word line driver transistors 722A and the second word line driver transistors 722B that are electrically connected to respective word lines 46W in the same respective memory block 99A or 99B has an areal overlap with the respective memory block 99A or 99B in a plan view along a vertical direction, and does not have any areal overlap with any other memory block of the memory blocks in the plan view. In other words, the source or drain region of the word line driver transistor 722 which is electrically connected to a word line 46W in a respective memory block 99A is located over or under the same respective memory block 99A, but not over or under other memory blocks 99B.

In one embodiment, for each of the first word line driver transistors 722A and the second word line driver transistors 722A, the respective first source/drain region 1 has an areal overlap only with a respective first one of the memory blocks 99A in a plan view along a vertical direction, and the respective second source/drain region 2 has an areal overlap only with a respective second one of the memory blocks 99B in the plan view, the second memory block 99B being different from the first memory block 99A. For example, the source or drain region 1 of the first word line driver transistors 722A which is electrically connected to the word line 46W in the first memory block 99A is located over or under the first memory block 99A. Likewise, the first source or drain region 1 of the second word line driver transistors 722B which is electrically connected to the word line 46W in the first memory block 99A is also located over or under the first memory block 99A. However, the second source or drain region 2 of the same second word line driver transistors 722B which is electrically connected to the word line 46W in the second memory block 99B is not located over or under the first memory block 99A, but is instead located over or under the second memory block 99B.

In one embodiment, all metal interconnect structures 780 that provide an electrical connection between a word line 46W in a respective memory block 99A and an output node 1 of a first word line driver transistor 722A or a second word line driver transistor 722A are located entirely within an area of the respective memory block 99A within a plan view along a vertical direction.

In one embodiment, the active semiconductor regions 4 have a same active region length along the second horizontal direction hd2 for each of the first word line driver transistors 722A and second word line driver transistors 722B; and the same active region length is the same or greater than the uniform block-to-block pitch p_bb.

In one embodiment, the word line driver transistors 722 straddle a boundary (e.g., the lateral trench isolation fill structure 76) between adjacent memory blocks 99A and 99B. For example, the active region 4 of each of the word line driver transistors 722 straddles (i.e., is located over or under) the boundary (e.g., the lateral trench isolation fill structure 76) between adjacent memory blocks 99A and 99B, such that the output nodes 1 and 2 of the same word line driver transistor 722 are located over or under different respective memory blocks 99A and 99B.

In one embodiment, the geometrical center of each first word line driver transistor 722A within a row of first word line driver transistors 722A in Transistor group A may be laterally offset along the second horizontal direction hd2 from the boundary (e.g., the lateral trench isolation fill structure 76) between a neighboring pair of memory blocks 99A and 99B by a first distance D1; and the geometrical center of each second word line driver transistor 722B within a row of second word line driver transistors 722B within Transistor group B may be laterally offset along the opposite direction of the second horizontal direction hd2 from the boundary (e.g., the lateral trench isolation fill structure 76) between the neighboring pair of memory blocks 99A and 99B by a second distance D2. The sum of the first distance D1 and the second distance D2 differs from the uniform transistor row-to-row pitch TRRP.

In one embodiment, the rows of the first word line driver transistors 722A are spaced along the second horizontal direction hd2 with a uniform transistor row-to-row pitch TRRP; the additional rows of the second word line driver transistors 722B are arranged spaced along the second horizontal direction hd2 with the uniform transistor row-to-row pitch TRRP; the uniform transistor row-to-row pitch TRRP is (n+1)/n times the uniform block-to-block pitch p_bb; and n is an integer greater than 1 and less than 7. In other words, n may be in integer selected from 2, 3, 4, 5, and 6.

In one embodiment, each row of output nodes (1, 2) of the word line driver transistors 722 constitutes a track of output nodes 1 or 2. Thus, each row of word line driver transistors 722 comprises two tracks of output nodes. For example the row of the first word line driver transistors 722A which straddles the boundary 76 between the first memory block 99A and the second memory block 99B includes Track-1 of output nodes 2 which are located above or below the first memory block 99A, and Track-2 of output nodes 1 which are located above or below the second memory block 99B. Five tracks (Track-0, Track-1, Track-2, Track-3 and Track-4) are shown in FIG. 12.

Generally, tracks within Transistor group A can be laterally offset from tracks within Transistor group B along the second horizontal direction hd2. Each track of output nodes having an areal overlap with a respective memory block 99A or 99B may be electrically connected to a respective word line 46W within the respective 99A or 99B memory block.

In one embodiment, the integer n is 2; the memory blocks comprise a first memory block (such as BLOCK A) 99A and a second memory block (such as BLOCK B) 99B; and each of the first word line driver transistors 722A and the second word line driver transistors 722B which has an output node 1 or 2 that is electrically connected to a word line 46W in the first memory block 99A, and comprises another output node 2 or 1 that is electrically connected to a respective word line 46W in another memory block (e.g., the second memory block 99B) that is not the first memory block 99A.

In one embodiment, the first word line driver transistors 722A comprise first-row first word line driver transistors 722A (which may be located, for example, in Track-1 and Track-2) and second-row first word line driver transistors 722A (which may be located, for example, in Track-3 and Track-4) that are spaced along the second horizontal direction hd2. The second word line driver transistors 722B comprise first-row second word line driver transistors 722B (which may be located, for example, in Track-0 and Track-1) and second-row second word line driver transistors 722B (which may be located, for example, in Track-2 and Track-3) that are spaced along the second horizontal direction hd2. In one embodiment, word lines 46W in the first memory block (such as BLOCK A) 99A are electrically connected by interconnection structures 780 to first output nodes 1 of the first-row first word line driver transistors 722A (which are located in Track-1), second output nodes 2 of the first-row second word line driver transistors 722B (which are located in Track-1), and first output nodes 1 of the second-row second word line driver transistors 722B (which are located in Track 2). Word lines 46W of the second memory block (such as BLOCK B) 99B are electrically connected to second output nodes 2 of the first-row first word line driver transistors 722A (which are located in Track-2), first output nodes 1 of the second-row first word line driver transistors 722A (which are located in Track-3), and second output nodes 2 of the second-row second word line driver transistors 722B (which are located in Track-3).

In one embodiment, the respective first word line 46W is located in a respective first memory block 99A; and the respective second word line 46W is located in a respective second memory block 99B, the second memory block 99B being a neighboring memory block of the first memory block 99A. In one embodiment, the memory die 900 comprises rows of layer contact via structures 86 that are arranged along the first horizontal direction hd1; and each row of layer contact via structures 86 electrically and/or physically contacts word lines 46W within a respective alternating stack (32, 46).

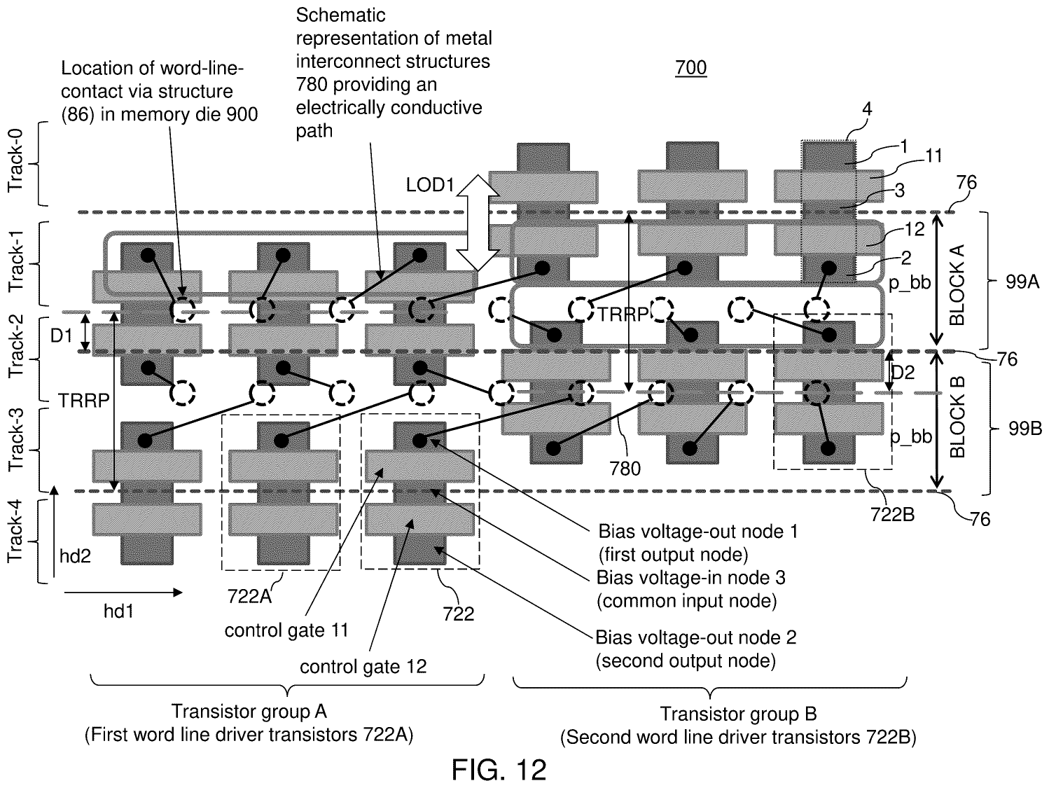

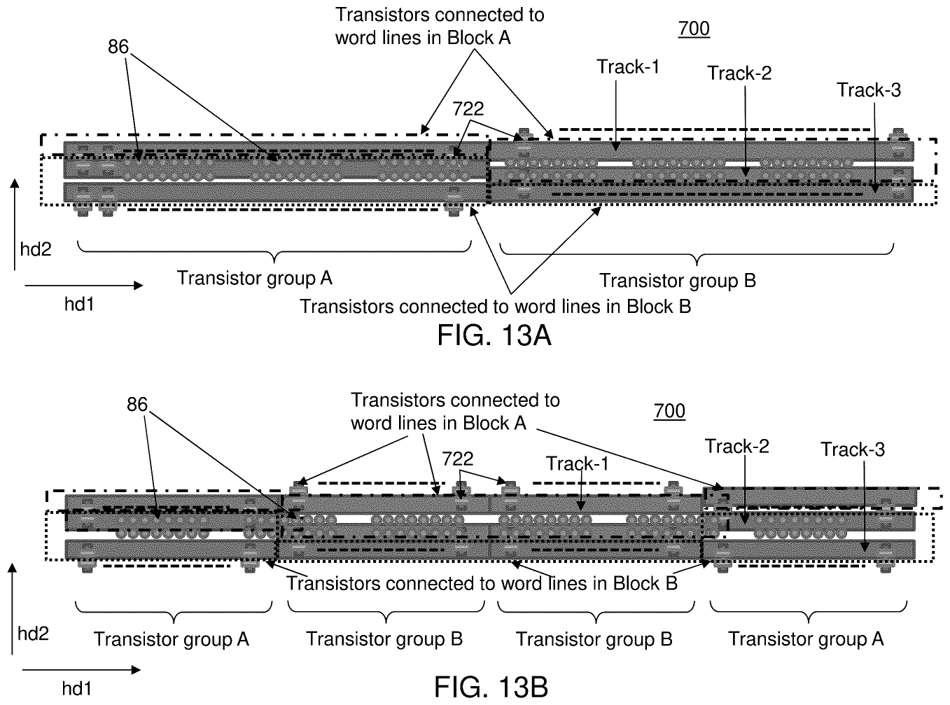

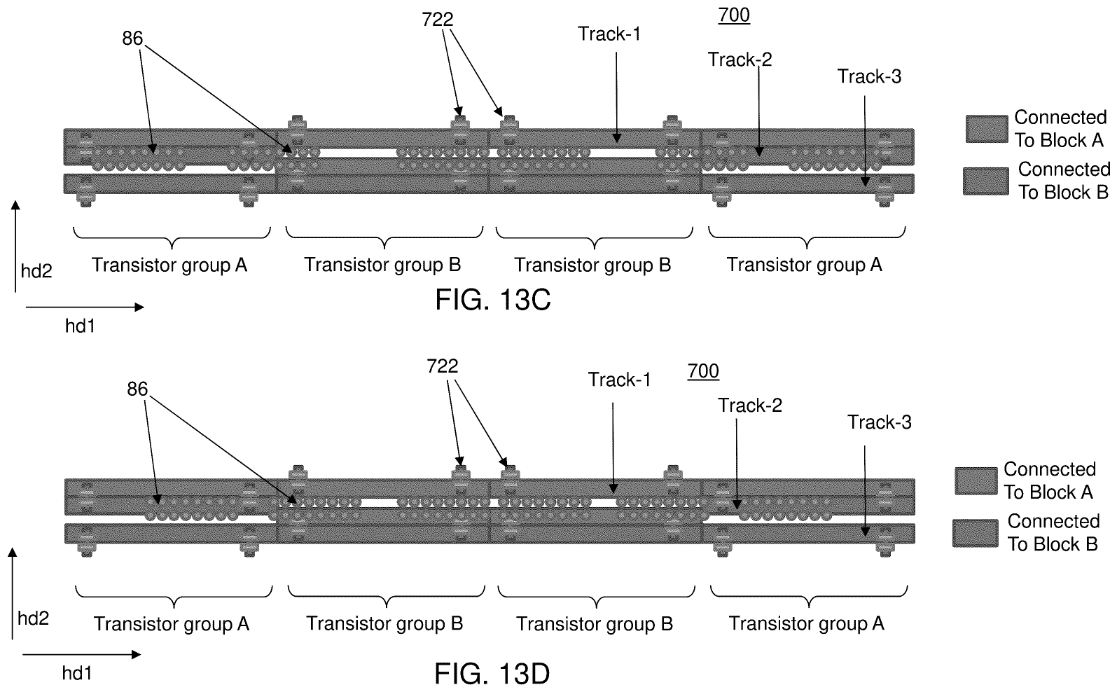

FIGS. 13A-13D are plan views of second configurations of the exemplary structure in which word line driver transistors 722 in the logic die 700 are shown according to an embodiment of the present disclosure. Each row of layer contact via structures 86 is formed within the area of a respective memory block in the memory die 900. Each neighboring pair of rows of layer contact via structures 86 is formed over a respective neighboring pair of memory blocks 99A, 99B in the memory die 900.

Referring to FIG. 13A, Transistor group A and Transistor group B can be laterally spaced from each other along the first horizontal direction hd1. Each transistor group may be electrically connected to multiple rows of layer contact via structures 86 that are electrically connected to a word line 46W in a respective memory block.

Referring to FIG. 13B, two instances Transistor group A and two instances of Transistor group B can be arranged along the first horizontal direction hd1 with a mirror symmetry along a vertical plane that is perpendicular to the first horizontal direction hd1. A subset of the layer contact via structures 86 may be arranged as an array that extends across a boundary between an instance of Transistor group A and an instance of Transistor group B. FIGS. 13C and 13D illustrate alternative arrangements of two instances Transistor group A and two instances of Transistor group B.

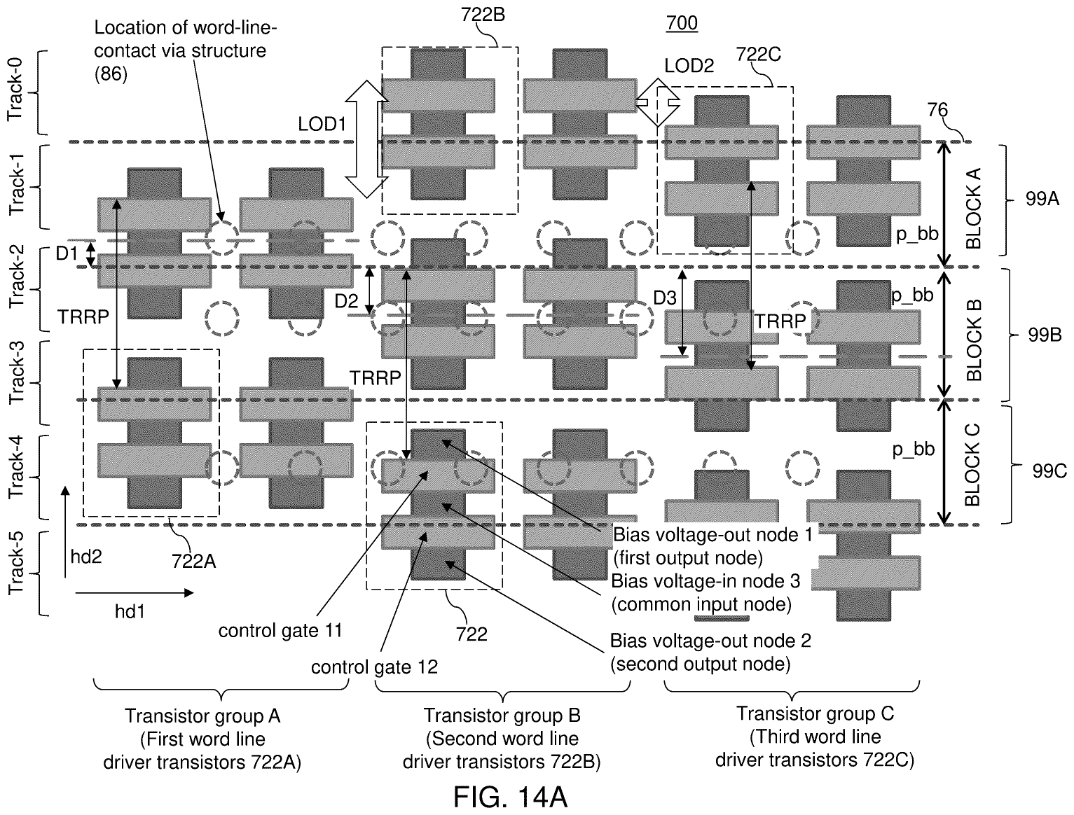

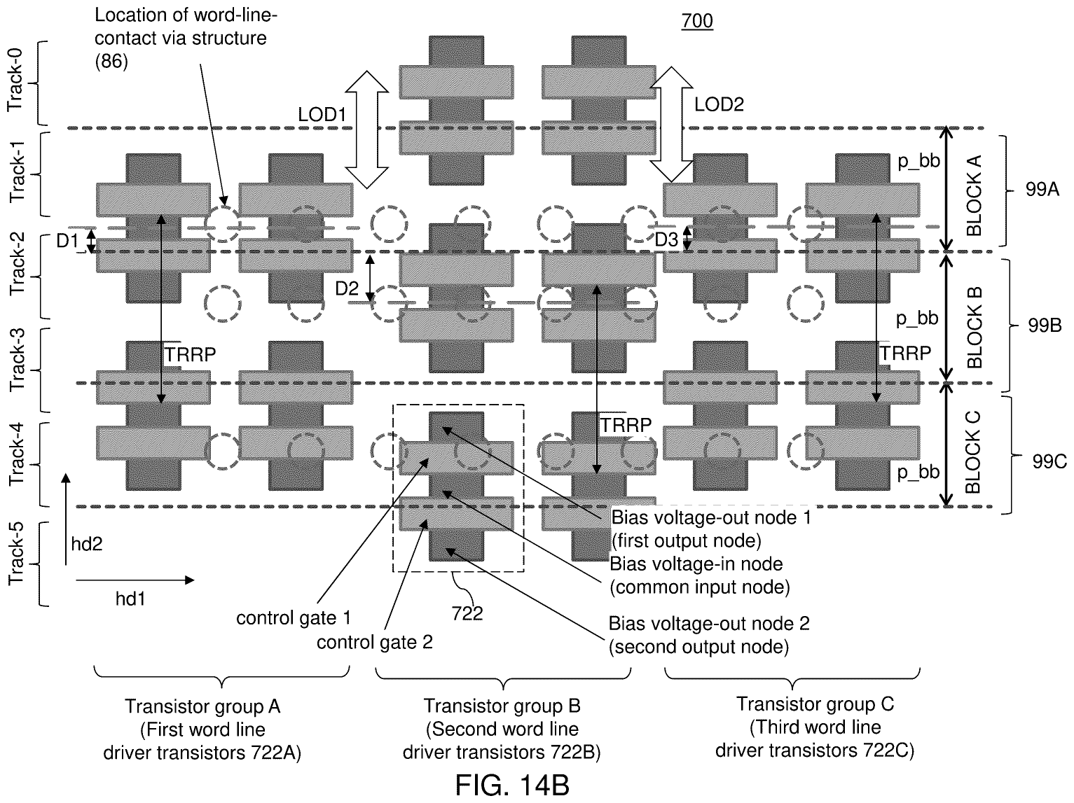

FIGS. 14A and 14B are plan views of third configurations of the exemplary structure in which word line driver transistors 722 in the logic die 700 are juxtaposed over blocks in the memory die 900 according to an embodiment of the present disclosure. FIGS. 14A and 14B illustrate a case in which the integer n is 3.

In one embodiment, the memory blocks comprise a first memory block (such as BLOCK A) 99A, a second memory block (such as BLOCK B) 99B, and a third memory block (such as BLOCK C) 99C. Each of the first word line driver transistors 722 and the second word line driver transistors 722 which has an output node that is electrically connected to a word line 46W in the first memory block comprises another output node that is electrically connected to a respective word line 46W in a memory block that is not the first memory block.

In one embodiment, the first word line driver transistors 722 are arranged in rows that extend along the first horizontal direction hd1 and spaced apart among one another along the second horizontal direction hd2. The second word line driver transistors 722 are arranged in additional rows that extend along the first horizontal direction hd1 and spaced apart among one another along the second horizontal direction hd2. The third word line driver transistors 722 are arranged in yet additional rows that extend along the first horizontal direction hd1 and spaced apart among one another along the second horizontal direction hd2. In one embodiment, the rows of the first word line driver transistors 722 and the additional rows of the second word line driver transistors 722 are offset along the second horizontal direction hd2 by a uniform lateral offset distance such as a first lateral offset distance LOD1. In one embodiment, the rows of the second word line driver transistors 722 and the rows of the third word line driver transistors 722 are offset along the second horizontal direction hd2 by a uniform lateral offset distance such as a second lateral offset distance LOD2. The first lateral offset distance LOD1 is different from the uniform transistor row-to-row pitch TRRP. The second lateral offset distance LOD2 is different from the uniform transistor row-to-row pitch TRRP.

In one embodiment, the geometrical center of each first word line driver transistor 722 within a row of first word line driver transistors 722 in Transistor group A may be laterally offset along the second horizontal direction hd2 from a boundary between a neighboring pair of memory blocks (such as the boundary between BLOCK A and BLOCK B) by a first distance D1; and the geometrical center of each second word line driver transistor 722 within a row of second word line driver transistors 722 within Transistor group B may be laterally offset along the opposite direction of the second horizontal direction hd2 from the boundary between the neighboring pair of memory blocks (such as the boundary between BLOCK A and BLOCK B) by a second distance D1. The sum of the first distance D1 and the second distance D2 differs from the uniform transistor row-to-row pitch TRRP. In one embodiment, the geometrical center of each third word line driver transistor 722 within a row of third word line driver transistors 722 in Transistor group C may be laterally offset along the second horizontal direction hd2 from a boundary between a neighboring pair of memory blocks (such as the boundary between BLOCK A and BLOCK B) by a third distance D3, which is different from the first distance D1. The sum of the third distance D3 and the second distance D2 differs from the uniform transistor row-to-row pitch TRRP.

In one embodiment, the first word line driver transistors 722 comprise first-row first word line driver transistors 722 (which are located in Track 1 and Track 2) and second-row first word line driver transistors 722 (which are located in Track 3 and Track 4) that are spaced along the second horizontal direction hd2; the second word line driver transistors 722 comprise first-row second word line driver transistors 722 (which are located in Track 0 and Track 1), second-row second word line driver transistors 722 (which are located in Track 2 and Track 3), and third-row second word line driver transistors 722 (which are located in Track 4 and Track 5) that are spaced along the second horizontal direction hd2. In one embodiment, first output nodes of the first-row first word line driver transistors 722 (which are located in Track 1), second output nodes of the first-row second word line driver transistors 722 (which are located in Track 1), and first output nodes of the second-row second word line driver transistors 722 (which are located in Track 2) are electrically connected to a respective word line 46W in the first memory block; second output nodes of the first-row first word line driver transistors 722 (which are located in Track 2), first output nodes of the second-row first word line driver transistors 722 (which are located in Track 3), and second output nodes of the second-row second word line driver transistors 722 (which are located in Track 3) are electrically connected to a respective word line 46W in the second memory block. Second output nodes of the second-row first word line driver transistors 722 (which are located in Track 4) and first output nodes of the third-row second word line driver transistors 722 (which are located in Track 4) are electrically connected to a respective word line 46W in the third memory block.

Referring to FIG. 14A, third word line driver transistors 722C may be provided within Transistor group C, which is laterally offset from Transistor group B along the first horizontal direction hd1. The third word line driver transistors 722C comprise first-row third word line driver transistors 722C (which are located in Track-0 and Track-1), second-row third word line driver transistors 722C (which are located in Track-2 and Track-3), and third-row third word line driver transistors 722C (which are located in Track-4 and Track-5) that are spaced along the second horizontal direction hd2. In one embodiment, second output nodes 2 of the first-row third word line driver transistors 722C (which are located in Track-1) are electrically connected to a respective word line 46W in the first memory block (i.e., BLOCK A) 99A; first output nodes 1 of the second-row third word line driver transistors 722C (which are located in Track-2) are electrically connected to a respective word line 46W in the second memory block (i.e., BLOCK B) 99B, and second output nodes 2 of the second-row third word line driver transistors 722C (which are located in Track-3) and first output nodes 1 of the third-row third word line driver transistors 722C (which are located in Track-4) are electrically connected to a respective word line 46W in the third memory block (i.e., BLOCK C) 99C.

Referring to FIG. 14B, third word line driver transistors 722C may be provided within Transistor group C, which is laterally offset from Transistor group B along the first horizontal direction hd1. The third word line driver transistors 722C comprise first-row third word line driver transistors 722C (which are located in Track-1 and Track-2), and second-row third word line driver transistors 722C (which are located in Track-3 and Track-4) that are spaced along the second horizontal direction hd2. In one embodiment, first output nodes 1 of the first-row third word line driver transistors 722C (which are located in Track-1) are electrically connected to a respective word line 46W in the first memory block (i.e., BLOCK A) 99A; second output nodes 2 of the first-row third word line driver transistors 722C (which are located in Track-2) and first output nodes 1 of the second-row third word line driver transistors 722C (which are located in Track-3) are electrically connected to a respective word line 46W in the second memory block (i.e., BLOCK B) 99B, and second output nodes 2 of the second-row third word line driver transistors 722C (which are located in Track-4) are electrically connected to a respective word line 46W in the third memory block (i.e., BLOCK C) 99C.

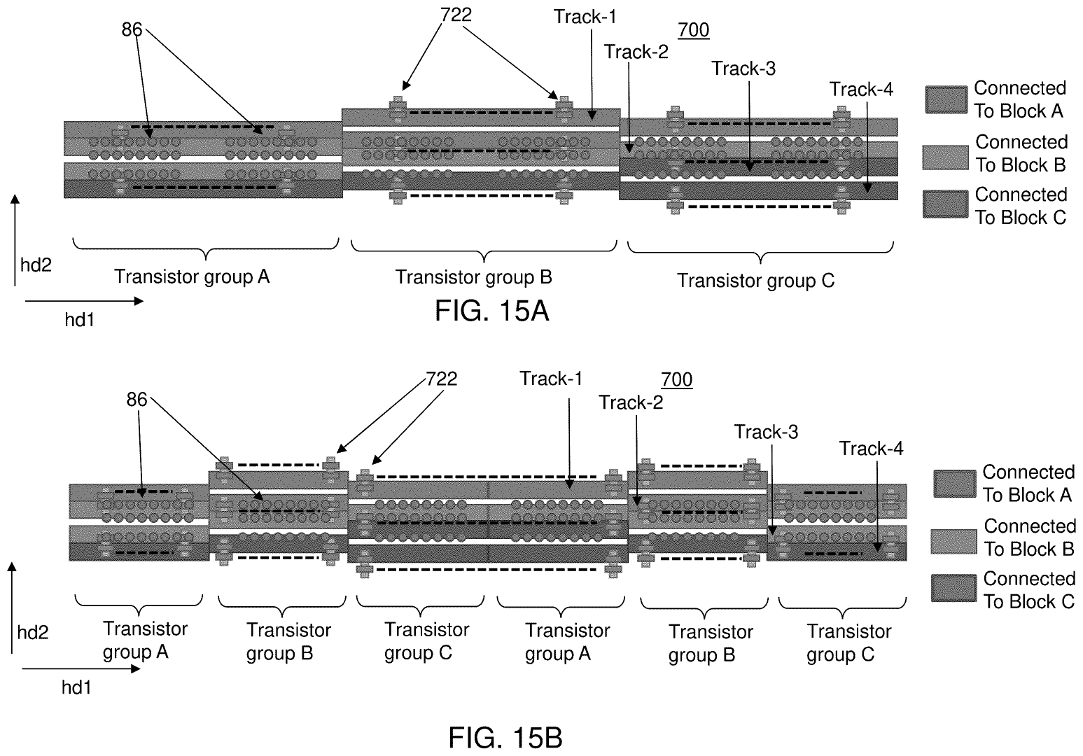

FIGS. 15A and 15B are plan views of fourth configurations of the exemplary structure in which word line driver transistors 722 in the logic die 700 are shown according to an embodiment of the present disclosure. Each row of layer contact via structures 86 is formed within the area of a respective memory block in the memory die 900. Each neighboring pair of rows of layer contact via structures 86 is formed over a respective neighboring pair of memory blocks in the memory die 900.

Referring to FIG. 15A, Transistor group A, Transistor group B, and Transistor group C can be laterally spaced from each other along the first horizontal direction hd1. Each transistor group may be electrically connected to multiple rows of layer contact via structures 86 that are electrically connected to word lines 46W in a respective memory block.

Referring to FIG. 15B, two instances Transistor group A, two instances of Transistor group B, and two instances of Transistor group C can be arranged along the first horizontal direction hd1 with a mirror symmetry along a vertical plane that is perpendicular to the first horizontal direction hd1.

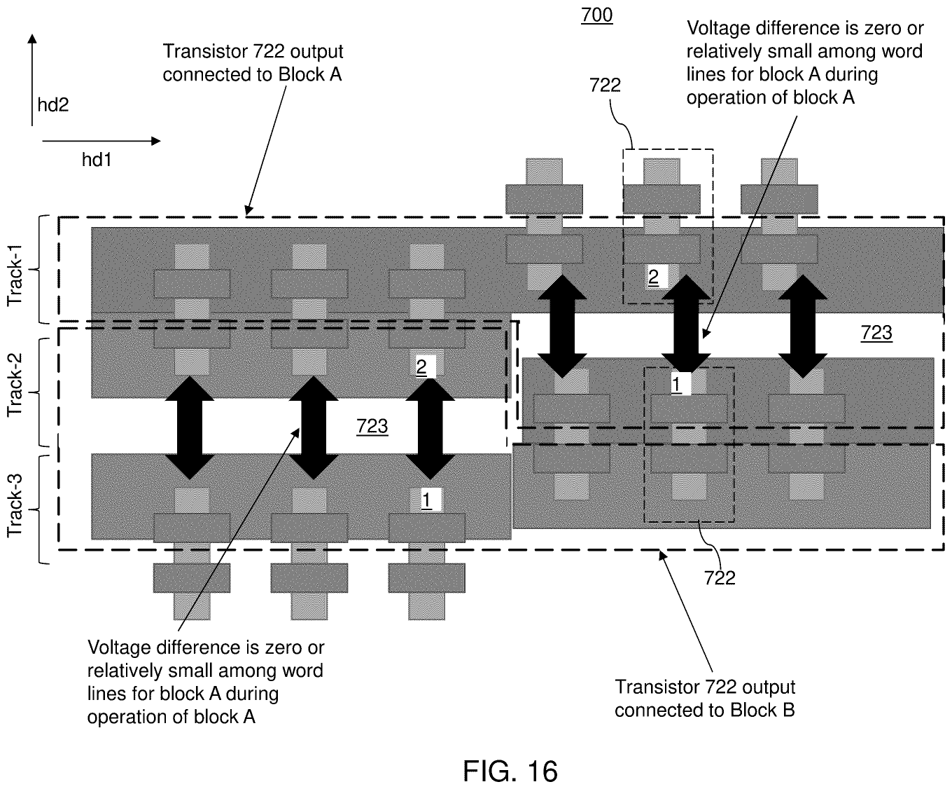

FIG. 16 is a plan view of a fifth configuration of the exemplary structure in which word line driver transistors 722 in the logic die 700 are shown according to an embodiment of the present disclosure.

In the fifth configuration, a pair of output nodes 1 and 2 of the adjacent word line driver transistors 722 that are laterally spaced apart along the second horizontal direction hd2 by a dielectric isolation structure (such as a shallow trench isolation structure) 723 can be electrically connected to a same memory block (e.g., 99A or 99B). For example, output nodes 1 and 2 of the word line driver transistors 722 located within each dashed area can be electrically connected to word lines 46W within a same memory block (99A or 99B). In this case, the maximum of the voltage difference between the neighboring pairs of output nodes 1 and 2 of adjacent transistors 722 that are electrically connected to word lines 46W in the same memory block 99A can be smaller than the maximum of the voltage difference for two output nodes 1 and 2 of adjacent transistors 722 that are electrically connected to word lines in different memory blocks 99A and 99B. Thus, the lateral dimension of the dielectric isolation structure 723 along the second horizontal direction hd2 can be reduced, and the layout of the word line driver transistors 722 may become more compact. Thus, according to an aspect of the present disclosure, a neighboring pair of output nodes 1 and 2 of adjacent transistors 722 that are laterally spaced from each other by a dielectric isolation structure 723 can be electrically connected to word lines 46W located within a same memory block 99A or 99B, and the lateral spacing between the neighboring pair of output nodes may be reduced.

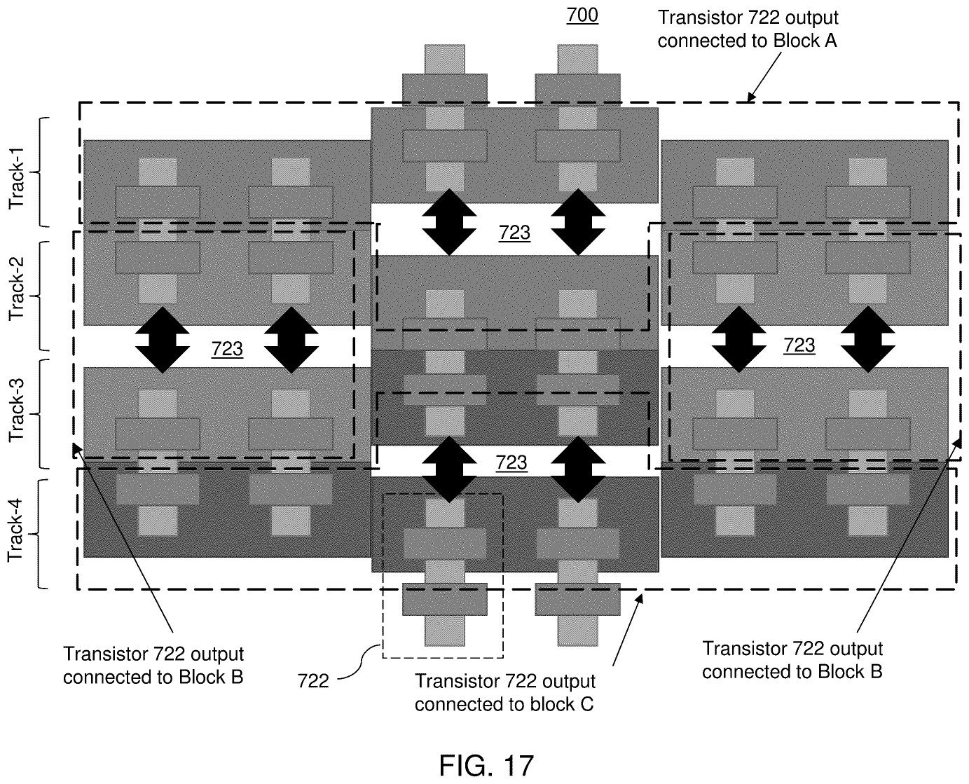

FIG. 17 is a plan view of a sixth configuration of the exemplary structure in which word line driver transistors 722 in the logic die 700 are shown according to an embodiment of the present disclosure. In the illustrated example, output nodes 1 and 2 of the word line driver transistors 722 located within each dotted area can be electrically connected to word lines 46W within a same memory block (99A, 99B or 99C).

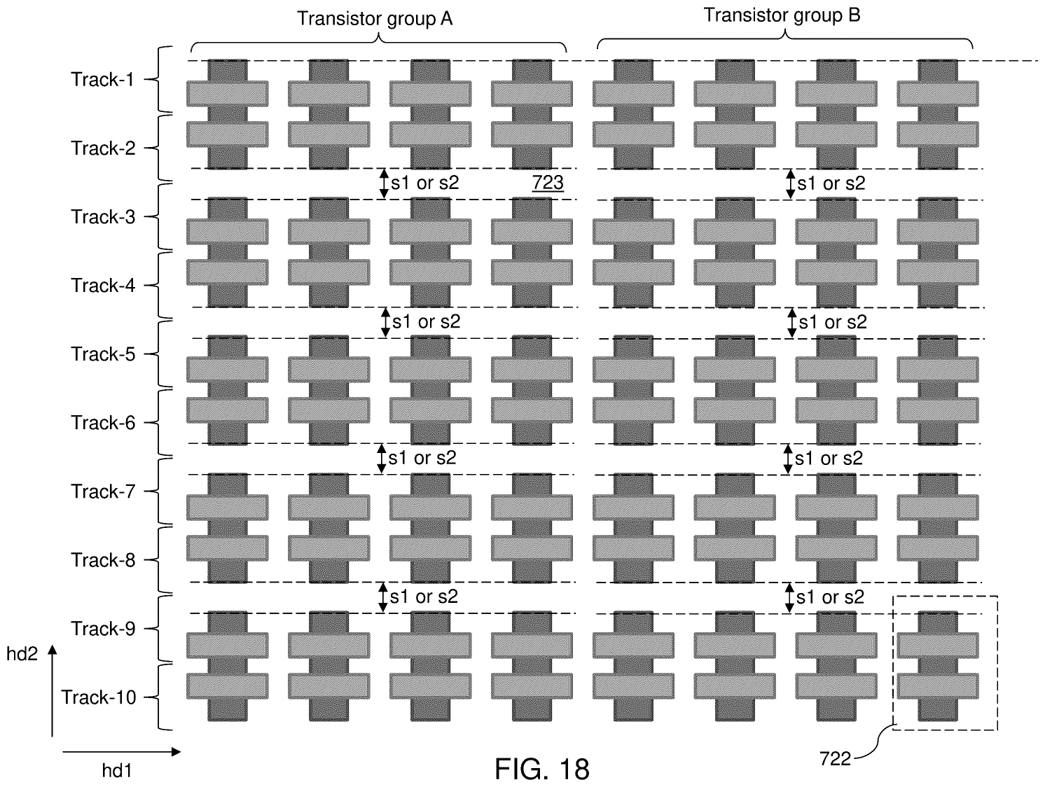

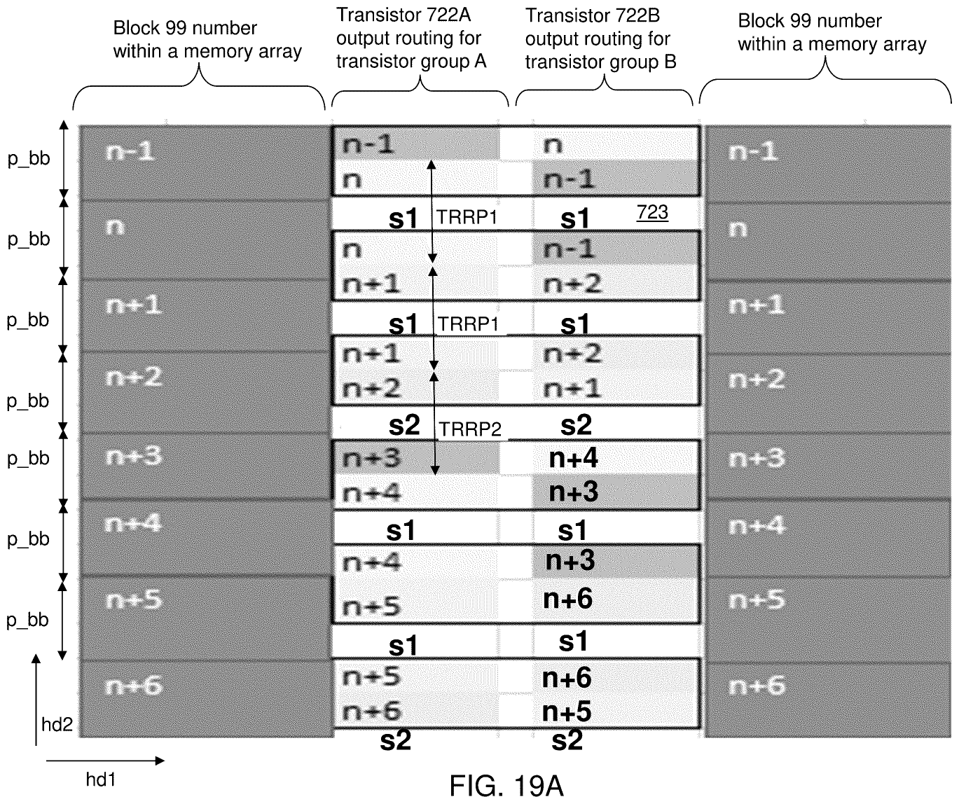

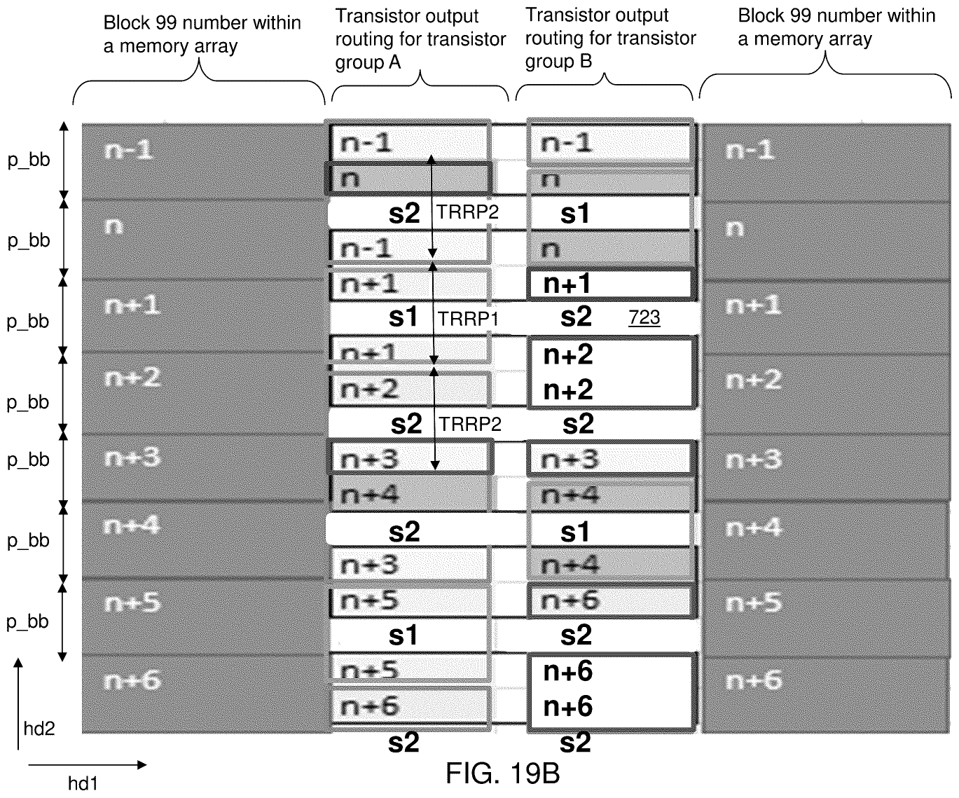

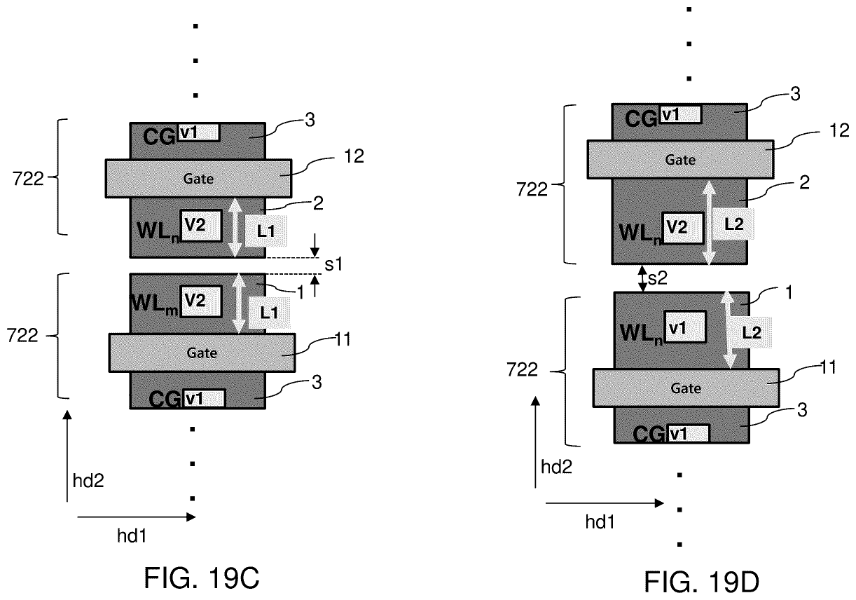

FIG. 18 is a plan view of a seventh configuration of the exemplary structure in which word line driver transistors 722 in the logic die 700 are shown according to an embodiment of the present disclosure. FIGS. 19A and 19B are first schematic diagrams illustrating the spatial overlap between the seventh configuration transistor groups in the logic die 700 and memory blocks in the memory die 900 according to an embodiment of the present disclosure. In FIGS. 19A and 19B, the memory block 99 numbers are represented by numbers such as n−1, n, n+1, n+2, n+3, n+4, n+5, and n+6. The numbers of the memory blocks 99 to which outputs of the word line driver transistors 722 are electrically connected to are represented by “Transistor output routing for transistor group” A or B.

In this embodiment, the rows of first word line driver transistors 722A in transistor group A may be laterally offset from the rows of the second word line driver transistors 722B in transistor group B along the second horizontal direction hd2, as described above with respect to FIGS. 12 to 17. Alternatively, the rows of first word line driver transistors 722A in transistor group A may be not be laterally offset from the rows of the second word line driver transistors 722B along the second horizontal direction hd2. In this case, the first word line driver transistors 722A in transistor group A may be located in the same rows extending along the first horizontal direction hd1 as the second word line driver transistors 722B. In other words, a single row of word line driver transistors 722 extending along the first horizontal direction hd1 may include both first and second word line driver transistors 722A and 722B.

As discussed above, each word line driver transistor 722 comprises a first output node (i.e., a bias voltage-out node 1) that is electrically connected to a respective first word line 46W of the memory blocks 99 and laterally spaced from a common input node (i.e., a bias voltage-in node 3) by a respective first control gate electrode 11 along the second horizontal direction hd2 (e.g., along the source to drain direction), and further comprises a second output node (i.e., a bias voltage-out node 2) that is electrically connected to a respective second word line 46W of the memory blocks 99 and laterally spaced from the common input node 3 by a respective second control gate electrode along a direction (e.g., the drain to source direction) that is an opposite (i.e., differs by 180 degrees) direction of the second horizontal direction hd2. The source to drain direction and the drain to source direction are collectively referred to as the source-drain direction.

Referring to FIGS. 19A and 19B, each vertically adjacent pair of numbers (such as a combination of n−1 and n) within the Transistor output routing for transistor group A column represents a pair of memory blocks 99 to which the at least one (or both) of the two output nodes (1, 2) of each word line driver transistors 722 within transistor group A are connected. Likewise, each vertically adjacent pair of numbers (such as a combination of n and n−1) within the Transistor output routing for transistor group B column represents a pair of memory blocks 99 to which the at least one (or both) of the two output nodes (1, 2) of each word line driver transistors 722 within transistor group B are connected.

According to an aspect of the present disclosure, at least a subset of neighboring pairs of output nodes 1 and 2 of adjacent word line driver transistors 722 that are spaced by dielectric isolation structures (such as shallow trench isolation structures) 732 along the second horizontal direction hd2 (e.g., along the source-drain direction) can be electrically connected to word lines 46W within a same memory block 99 (such as memory block n). In this case, a reduced lateral spacing (which is herein referred to as a first spacing s1) between these output nodes 1 and 2 may be employed in lieu of a nominal lateral spacing (which is herein referred to as a second spacing s2) between output nodes 1 and 2 which are electrically connected to word lines of different memory blocks 99. In other words, if the output nodes (i.e., source or drain regions) 1 and 2 of laterally adjacent word line driver transistors 722 in the same transistor group which are separated by dielectric isolation structure 723 along their source-drain direction are electrically connected to word lines 46W of the same memory block 99, then the width s1 of the dielectric isolation structure 723 along the source-drain direction may be smaller than the width s2 of the dielectric isolation structure 723 which separates nodes (i.e., source or drain regions) 1 and 2 of laterally adjacent word line driver transistors 722 in the same transistor group which are electrically connected to word lines 46W of different memory blocks 99.

As discussed above with respect to FIG. 16, a maximum of the voltage difference between the neighboring pairs of output nodes 1 and 2 of adjacent transistors 722 that are electrically connected to word lines 46W in the same memory block 99 can be smaller than the maximum of the voltage difference for two output nodes 1 and 2 of adjacent transistors 722 that are electrically connected to word lines in different memory blocks 99. In this case, the width of the dielectric isolation structure 723 between the output nodes which are electrically connected to word lines of the same memory block may be reduced due to the lower voltage difference. The difference between the first spacing s1 and the second spacing s2 may be between 10 and 80 percent, such as between 30 and 50 percent, for example between 100 nm and 1,000 nm, such as 200 nm to 400 nm.

In an illustrative example, if the erase voltage employed for operation of a three-dimensional memory device is about 30 V, the first spacing s1 may be 350 to 450 nm, and the second spacing s2 may be 750 to 850 nm. By employing the reduced first spacing s1 for a subset of lateral spacings along the second horizontal direction hd2 between neighboring pairs of word line driver transistors 722, the overall lateral dimension of the arrays of word line driver transistors 722 along the second horizontal direction hd2 (e.g., along the transistor source-drain direction) can be reduced, and the total area occupied by the word line driver transistors 722 may be reduced.

In the seventh configuration of the exemplary structure, the memory die 900 comprises a plurality of memory blocks 99 including a respective alternating stack of insulating layers 32 and word lines 46W and including a respective set of rows of memory opening fill structures (e.g., vertical NAND strings) 58 vertically extending through the respective alternating stack and arranged along a first horizontal direction hd1. The memory blocks 99 are laterally spaced apart from each other along a second horizontal direction hd2 that is perpendicular to the first horizontal direction hd1 with a uniform block-to-block pitch p_bb.

The logic die 700 comprises a first two-dimensional array (e.g., transistor Group A) of first word line driver transistors 722A including multiple rows of first word line driver transistors 722A, and a second two-dimensional array of second word line driver transistors 722B including multiple rows of second word line driver transistors 722B. Each row of first word line driver transistors 722A is arranged along the first horizontal direction hd1 and each row of second word line driver transistors 722B is arranged along the first horizontal direction hd1. Each of the first word line driver transistors 722A and the second word line driver transistors 722B comprises a first output node 1 that is electrically connected to a respective first word line 46W of the memory blocks 99 and laterally spaced from a common input node 3 by a respective first control gate electrode 11 along the second horizontal direction hd2, and further comprises a second output node 2 that is electrically connected to a respective second word line 46W of the memory blocks 99 and laterally spaced from the common input node 3 by a respective second control gate electrode 12 along a direction that is an opposite direction of the second horizontal direction hd2.

The multiple rows of first word line driver transistors 722A have a periodic modulation in a first row-to-row spacing along the second horizontal direction hd2. The first row-to-row spacing is measured by a lateral spacing between a neighboring pair of first word line driver transistors 722A that are laterally spaced along the second horizontal direction hd2.

In the example illustrated in FIG. 19A, the first row-to-row spacing along the second horizontal direction hd2 for the multiple rows of first word line driver transistors 722A may have a sequence of s1, s1, s2, s1, s1, s2, etc. Thus, the first row-to-row spacing along the second horizontal direction hd2 has a periodic modulation such that every third spacing has a value of s2, while all other spacings have a value of s1. Therefore, two thirds of the adjacent transistors 722 which are spaced along the source-drain direction by a dielectric isolation structure 723 have the reduced spacing s1, while one third of the transistors 722 have the larger nominal spacing s2.

In the example illustrated in FIG. 19B, the first row-to-row spacing along the second horizontal direction hd2 for the multiple rows of first word line driver transistors 722A may have a sequence of s1, s2, s2, s1, s2, s2, etc. Thus, the first row-to-row spacing along the second horizontal direction hd2 has a periodic modulation such that every third spacing has a value of s1, while all other spacings have a value of s2. Therefore, one third of the adjacent transistors 722 which are spaced along the source-drain direction by a dielectric isolation structure 723 have the reduced spacing s1, while two thirds of the transistors 722 have the larger nominal spacing s2.

Accordingly, the transistor row-to-row pitch has two values. If the two rows of word line driver transistors 722 are spaced by spacing s1, the two rows of word-line driver transistors 722 may have a first row-to-row pitch TRRP1. If the two rows of word line driver transistors 722 are spaced by spacing s2, the two rows of word-line driver transistors 722 may have a second row-to-row pitch TRRP2. The difference between the second row-to-row pitch TRRP2 and the first row-to-row pitch TRRP1 can be the same as the difference between spacings s2 and s1.

In one embodiment, each instance of the first row-to-row spacing s1 is provided between a second output node 2 of a respective one of the first word line driver transistors 722A and a first output node 1 of a respective additional one of the first word line driver transistors 722A. The first row-to-row spacing has a first value s1 if the second output node 2 of the respective one of the first word line driver transistors 722A and the first output node 1 of the respective additional one of the first word line driver transistors 722A are electrically connected to word lines 46W within a same memory block 99. In contrast, the first row-to-row spacing has a second value s2 larger than the first value s1 if the second output node 2 of the respective one of the first word line driver transistors 722A and the first output node 1 of the respective additional one of the first word line driver transistors 722A are electrically connected to word lines 46W in two different memory blocks 99.

In one embodiment, a sequence of the first row-to-row spacing as measured along the second horizontal direction hd2 (e.g., along the source-drain direction of the transistors 722) has a periodicity such that every n-th value of the first row-to-row spacing is the same. The value of the integer n may be greater than 1 and less than 13. In one embodiment, each of the first word line driver transistors 722A have a first transistor length along the second horizontal direction hd2 (e.g., along the source-drain direction); and a sum of n times the first transistor length and a consecutive sequence of n first row-to-row spacings equals (n+1) times the uniform block-to-block pitch p_bb. In the illustrated examples in FIGS. 19A and 19B, n is 3. Thus, each memory block 99 contains word lines 46W which are electrically connected to the word line driver transistors 722 that are located in three different rows in two different transistor groups.

In one embodiment, the multiple rows of second word line driver transistors 722B have a periodic modulation in a second row-to-row spacing along the second horizontal direction hd2, the second row-to-row spacing being measured by a lateral spacing between a neighboring pair of second word line driver transistors 722B that are laterally spaced along the second horizontal direction hd2. In one embodiment, the respective first word line 46W is located in a respective first memory block 99 of the memory blocks; and the respective second word line 46W is located in a respective second memory block 99 of the memory blocks, the second memory block being a neighboring memory block of the first memory block.

In another embodiment illustrated in FIGS. 19C and 19D, the active region length of some word line driver transistors 722 may be different from the active region length of other word line driver transistors 722 in the same transistor group.

FIG. 19C illustrates two laterally adjacent word line driver transistors 722 in the same transistor group (e.g. group A) which have respective output nodes 1 and 2 that are electrically connected to word lines 46W of the same memory block 99 (e.g., block n), and which are separated by the first spacing s1 along their source-drain direction (e.g., the second horizontal direction). In this case, the output nodes 1 and 2 (i.e., source or drain regions) of these transistors 722 have a relatively small first length L1 along their source-drain direction due to the low voltage difference between the word lines of the same memory block 99.

FIG. 19D illustrates two laterally adjacent word line driver transistors 722 in the same transistor group (e.g. group A) which have respective output nodes 1 and 2 that are electrically connected to word lines 46W of the different memory blocks 99 (e.g., block n and block n+1), and which are separated by the second spacing s2 along their source-drain direction (e.g., the second horizontal direction). In this case, the output nodes 1 and 2 (i.e., source or drain regions) of these transistors 722 have a relatively large second length L2 along their source-drain direction due to the larger voltage difference between word lines of different blocks 99. The second length L2 is larger than the first length L1. For example, the second length L2 may be 10 to 80 percent, such as 30 to 50 percent greater than the first length L1. The reduced source or drain length L1 of some word line switching transistors 722 further reduces the footprint of the word line driver circuit.

If the transistors 722 shown in FIGS. 19C and 19D are located in transistor group A of FIG. 19A, then two thirds of the adjacent transistors 722 which are spaced along the source-drain direction by a dielectric isolation structure 723 have the reduced spacing s1 and the reduced source or drain length L1, while one third of the transistors 722 have the larger nominal spacing s2 and the larger source or drain length L2.

If the transistors 722 shown in FIGS. 19C and 19D are located in transistor group A of FIG. 19B, then one third of the adjacent transistors 722 which are spaced along the source-drain direction by a dielectric isolation structure 723 have the reduced spacing s1 and the reduced source or drain length L1, while two thirds of the transistors 722 have the larger nominal spacing s2 and the larger source or drain length L2.

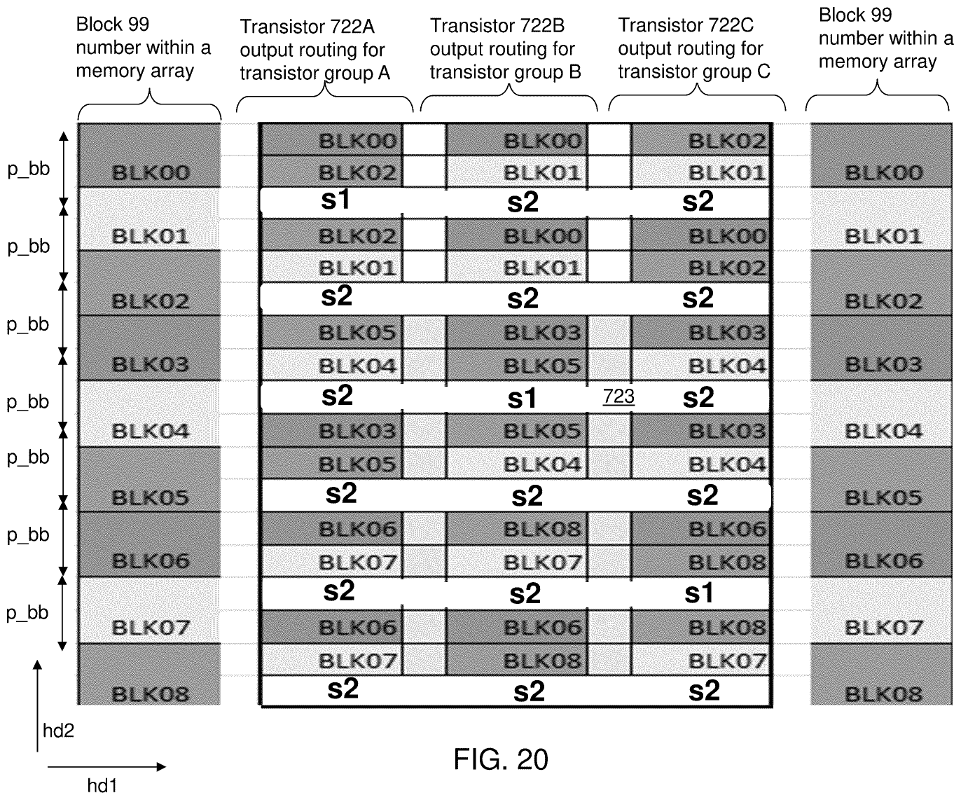

FIG. 20 is a second schematic diagram illustrating the spatial overlap between transistor groups in the logic die 700 and memory blocks in the memory die 900 according to an embodiment of the present disclosure. FIG. 20 illustrates a configuration in which three Transistor groups (i.e., Transistor group A, Transistor group B, and Transistor group C) are employed. In FIG. 20, each memory block 99 is represented by BLK ##, in which ## represents the block number. The “Block 99 number within a memory array” represents the memory blocks 99 within the memory die 900. The memory block 99 names within the Transistor output routing for the various transistor groups represent the memory blocks containing the word lines 46W to which the output nodes of the word line driver transistors 722 are electrically connected.

At least a subset of neighboring pairs of output nodes 1 and 2 of adjacent transistors that are spaced by dielectric isolation structures (such as shallow trench isolation structures) 723 along the second horizontal direction hd2 can be electrically connected to word lines 46W within a same memory block 99 (such as memory block n). In this case, a reduced lateral spacing (which is herein referred to as a first spacing s1) may be employed in lieu of a larger nominal lateral spacing (which is herein referred to as a second spacing s2) as discussed above.

In the example illustrated in FIG. 20, about ⅙ of all lateral spacings along the second horizontal direction hd2 can be the first spacing s1, and about ⅚ of all lateral spacings along the second horizontal direction hd2 can be the second spacing s2. Thus, the first row-to-row spacing along the second horizontal direction hd2 has a periodic modulation such that every sixth spacing has a value of s1, while all other spacings have a value of s2.

Generally, the fraction of the first spacing s1 of all spacings along the second horizontal direction hd2 can be given by m/n, in which n is a positive integer in a range from 1 to 12, and m is a positive integer not greater than n.

The various embodiments of the present disclosure can be employed to reduce the footprint for the word line driver transistors 722 in the logic die 700, and to reduce the lateral extent of electrical wiring that is employed to electrically connect the output nodes of the word line driver transistors 722 in the logic die 700 to the layer contact via structures 86 in the memory die 900.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
a plurality of memory blocks comprising respective word lines; and
a word line driver circuit comprising rows of first word line driver transistors having a source-drain direction and additional rows of second word line driver transistors having the same source-drain direction as the first word line driver transistors,
wherein:
the first word line driver transistors comprise first output nodes electrically connected to word lines in a first memory block of the plurality of memory blocks;
the second word line driver transistors comprise second output nodes electrically connected to word lines in the first memory block of the plurality of memory blocks; and
the rows of the first word line driver transistors are laterally offset from the additional rows of the second word line driver transistors along the source-drain direction.

2. The memory device of claim 1, wherein:
the first output nodes comprise first source or drain regions of the first word line driver transistors; and
the second output nodes comprise second source or drain regions of the second word line driver transistors.

3. The memory device of claim 2, wherein each first source or drain region of the first word line driver transistors and each second source or drain region of the second word line driver transistors has an areal overlap with the first memory block in a plan view along a vertical direction, and does not have any areal overlap with any other memory block of the plurality of memory blocks in the plan view.

4. The memory device of claim 1, wherein:
the plurality of memory blocks are located in a memory die;
the word line driver circuit is located in a logic die; and
the memory die is bonded to the logic die.

5. The memory device of claim 4, wherein:
each of the plurality of memory blocks comprises a respective alternating stack of insulating layers and the word lines and including a respective set of rows of memory opening fill structures vertically extending through the respective alternating stack and arranged along a first horizontal direction;
the memory blocks are laterally spaced apart from each other along a second horizontal direction that is perpendicular to the first horizontal direction and parallel to the source-drain direction; and
wherein:
the first word line driver transistors are arranged in the rows that extend along the first horizontal direction and spaced apart from each other along the second horizontal direction;
the second word line driver transistors are arranged in the additional rows that extend along the first horizontal direction and spaced apart from each other along the second horizontal direction; and
the rows of the first word line driver transistors and the additional rows of the second word line driver transistors are offset along the second horizontal direction by a lateral offset distance.

6. The memory device of claim 5, wherein:
the first output nodes and the second output nodes are electrically connected to the word lines in the first memory block by interconnect structures; and
all interconnect structures that provide an electrical connection between a word line in the first memory block and the first output node of a first word line driver transistor or the second output node of the second word line driver transistor are located entirely within an area of the first memory block within a plan view along a vertical direction.

7. The memory device of claim 5, wherein:
the rows of the first word line driver transistors are arranged along the second horizontal direction with a uniform transistor row-to-row pitch;
the additional rows of the second word line driver transistors are arranged along the second horizontal direction with the uniform transistor row-to-row pitch;
the uniform transistor row-to-row pitch is (n+1)/n times the uniform block-to-block pitch; and
n is an integer greater than 1 and less than 7.

8. The memory device of claim 7, wherein:
n is 2;
the plurality of memory blocks further comprise a second memory block; and
each of the first word line driver transistors and the second word line driver transistors which has an output node that is electrically connected to a word line in the first memory block comprises another output node that is electrically connected to a respective word line in the second memory block.

9. The memory device of claim 8, wherein:
the first word line driver transistors comprise first-row first word line driver transistors and second-row first word line driver transistors that are spaced along the second horizontal direction;
the second word line driver transistors comprise first-row second word line driver transistors and second-row second word line driver transistors that are spaced along the second horizontal direction;
the word lines in the first memory block are electrically connected to the first output nodes of the first-row first word line driver transistors, second output nodes of the first-row second word line driver transistors, or first output nodes of the second-row second word line driver transistors; and
the word lines of the second memory block are electrically connected to the second output nodes of the first-row first word line driver transistors, first output nodes of the second-row first word line driver transistors, or second output nodes of the second-row second word line driver transistors.

10. The memory device of claim 7, wherein:
n is 3;
the plurality of memory blocks further comprise a second memory block, and a third memory block; and
each of the first word line driver transistors and the second word line driver transistors which has an output node that is electrically connected to the word line in the first memory block comprises another output node that is electrically connected to a respective word line in a memory block that is not the first memory block.

11. The memory device of claim 10, wherein:
the first word line driver transistors comprise first-row first word line driver transistors and second-row first word line driver transistors that are spaced along the second horizontal direction;
the second word line driver transistors comprise first-row second word line driver transistors, second-row second word line driver transistors, and third-row second word line driver transistors that are spaced along the second horizontal direction;
the first output nodes of the first-row first word line driver transistors, second output nodes of the first-row second word line driver transistors, and first output nodes of the second-row second word line driver transistors are electrically connected to the respective word line in the first memory block;
the second output nodes of the first-row first word line driver transistors, first output nodes of the second-row first word line driver transistors, and second output nodes of the second-row second word line driver transistors are electrically connected to a respective word line in the second memory block; and
second output nodes of the second-row first word line driver transistors and first output nodes of the third-row second word line driver transistors are electrically connected to a respective word line in the third memory block.

12. The memory device of claim 5, wherein:
the memory die further comprises rows of layer contact via structures that are arranged along the first horizontal direction; and
each row of layer contact via structures contacts word lines within a respective alternating stack of the alternating stacks.

13. The memory device of claim 5, wherein multiple rows of first word line driver transistors have a periodic modulation in a first row-to-row spacing along the second horizontal direction, the first row-to-row spacing being measured by a lateral spacing between a neighboring pair of first word line driver transistors that are laterally spaced along the second horizontal direction.

14. The memory device of claim 1, wherein the first word line driver transistors further comprise second output nodes electrically connected to word lines in a second memory block of the plurality of memory blocks, common input nodes, a first gate electrode located between the common input node and the first output node, and a second gate electrode located between the common input node and the first output node.

15. A memory device, comprising:
a plurality of memory blocks comprising respective word lines; and
a word line driver circuit comprising a first word line driver transistor having a source-drain direction, and second, third and fourth word line driver transistors having the same source-drain direction as the first word line driver transistors,
wherein:
the first word line driver transistor comprises a first output node having a first length electrically connected to a word line in a first memory block of the plurality of memory blocks;
the second word line driver transistor comprises a second output node having the first length electrically connected to a word line in the first memory block;
the third word line driver transistor comprises a first output node having a second length electrically connected to a word line in the first memory block;
the fourth word line driver transistor comprises a second output node having the second length electrically connected to a word line in a second memory block of the plurality of memory blocks;
the first word line driver transistor and the second word line driver transistor are laterally spaced apart along the source-drain direction apart by a first lateral spacing;
the third word line driver transistor and the fourth word line driver transistor are laterally spaced apart along the source-drain direction apart by a second lateral spacing; and
at least one of (i) the second lateral spacing is larger than the first lateral spacing, or (ii) the second length is longer than the first length.

16. The memory device of claim 15, wherein the second lateral spacing is larger than the first lateral spacing.

17. The memory device of claim 15, wherein the second length is longer than the first length.

18. The memory device of claim 15, wherein the second length is longer than the first length and the second lateral spacing is larger than the first lateral spacing.

19. The memory device of claim 15, wherein:
the first output node comprises a source or drain region of the first word line driver transistor;
the second output node comprises a source or drain region of the second word line driver transistor;
the third output node comprises a source or drain region of the third word line river transistor; and
the fourth output node comprises a source or drain region of the fourth word line driver transistor.

20. The memory device of claim 15, wherein:
the plurality of memory blocks are located in a memory die;
the word line driver circuit is located in a logic die; and
the memory die is bonded to the logic die.
